(19) United States
(12) Patent Application Publication
(10) Pub. No.: US 2014/0014947 A1
(43) Pub. Date: Jan. 16, 2014

(54) SEMICONDUCTOR DEVICE

(71) Applicant: Semiconductor Energy Laboratory Co., Ltd., Atsugi-shi (JP)

(72) Inventor: Shunpei YAMAZAKI, Setagaya (JP)

(21) Appl. No.: 13/932,759

(22) Filed: Jul. 1, 2013

(30) Foreign Application Priority Data
Jul. 13, 2012 (JP) 2012-157653

(51) Int. Cl. H01L 29/786

(52) U.S. Cl. CPC H01L 29/7869
USPC 257/43

(57) ABSTRACT

High field-effect mobility of a transistor including an oxide semiconductor is achieved. Further, a highly reliable semiconductor device including the transistor is provided. In a transistor having a structure in which oxide semiconductor layers are stacked over a gate electrode layer with a gate insulating layer interposed therebetween. An oxide semiconductor layer serving as a buffer layer for interface stabilization is provided between an insulating layer and an indium zinc oxide layer serving as a main current path (channel) of the transistor. The indium zinc oxide layer serving as a channel includes a crystalline portion. An oxide semiconductor which contains indium and zinc and has a larger energy gap than the indium zinc oxide layer is used for the oxide semiconductor layer serving as a buffer layer.

### BACKGROUND OF THE INVENTION

1. Field of the Invention

The invention disclosed in this specification and the like relates to a semiconductor device and a method for manufacturing the semiconductor device.

In this specification and the like, a semiconductor device refers to all types of devices which can function by utilizing semiconductor characteristics; an electro-optical device, an image display device, a semiconductor circuit, and an electronic appliance are all semiconductor devices.

2. Description of the Related Art

A technique by which a transistor is formed using a semiconductor thin film formed over a substrate having an insulating surface has been attracting attention. Such a transistor is applied to a wide range of electronic appliances such as an integrated circuit (IC) and an image display device (also simply referred to as display device). A silicon-based semiconductor material is widely known as a material for a semiconductor thin film applicable to a transistor. As another material, an oxide semiconductor has been attracting attention.

For example, a technique by which a transistor is formed using zinc oxide or an In—Ga—Zn-based oxide semiconductor as an oxide semiconductor is disclosed (see Patent Documents 1 and 2).

Non-Patent Document 1 discloses a transistor having a structure in which oxide semiconductors are stacked. In the structure disclosed in Non-Patent Document 1, however, an oxide semiconductor serving as a channel is in contact with a silicon oxide film; thus, silicon, which is a constituent element of the silicon oxide film, might be mixed in the channel as an impurity. The impurity mixed in the channel might degrade electrical characteristics of the transistor.
[Patent Document 1] Japanese Published Patent Application No. 2007-123861
[Patent Document 2] Japanese Published Patent Application No. 2007-096055

### [Non-Patent Document 1]

Arokia Nathan et al., “Amorphous Oxide TFTs: Progress and Issues”, SID 2012 Digest pp. 1-4.

### SUMMARY OF THE INVENTION

An object of one embodiment of the present invention is to achieve high field-effect mobility of a semiconductor device including an oxide semiconductor.

Another object of one embodiment of the present invention is to provide a highly reliable semiconductor device including an oxide semiconductor, in which variations in the electrical characteristics are suppressed.

Electrical characteristics of a transistor including an oxide semiconductor vary depending on the interface state between an oxide semiconductor layer and an insulating layer in contact with the oxide semiconductor layer. For example, scattering of carriers at the interface between the oxide semiconductor layer and the insulating layer in contact with the oxide semiconductor layer causes a reduction in the field-effect mobility of the transistor. In addition, a trap level (also referred to as interface level) existing at the interface causes variations in electrical characteristics (e.g., threshold voltage, subthreshold swing (S value), and field-effect mobility).

In view of the above, one embodiment of the present invention is a transistor having a structure in which oxide semiconductor layers are stacked over a gate electrode layer with a gate insulating layer interposed therebetween. An oxide semiconductor layer serving as a buffer layer for interface stabilization is provided between an insulating layer and an indium zinc oxide layer serving as a main current path (channel) of the transistor. The indium zinc oxide layer serving as a channel includes a crystalline portion. An oxide semiconductor which contains indium and zinc and has a larger energy gap than the indium zinc oxide layer is used for the oxide semiconductor layer serving as a buffer layer. Specifically, an oxide semiconductor containing, as constituent elements, indium, zinc, and a stabilizer for stabilizing the electrical characteristics of the oxide semiconductor layer is used.

The structure enables the channel to be away from the interface between the oxide semiconductor layer and the insulating layer in contact with the oxide semiconductor stack, leading to formation of a buried channel structure. For example, the structure described below can be specifically employed.

One embodiment of the present invention is a semiconductor device including a gate electrode layer, a gate insulating layer over the gate electrode layer, an oxide semiconductor stack overlapping with the gate electrode layer with the gate insulating layer interposed therebetween, and source and drain electrode layers electrically connected to the oxide semiconductor stack. The oxide semiconductor stack includes a first oxide semiconductor layer in contact with the gate insulating layer and a second oxide semiconductor layer over the first oxide semiconductor layer. The first oxide semiconductor layer contains indium and zinc as constituent elements and has a larger energy gap than the second oxide semiconductor layer. The second oxide semiconductor layer is an indium zinc oxide layer including a crystalline portion.

Another embodiment of the present invention is a semiconductor device including a gate electrode layer, a gate insulating layer over the gate electrode layer, an oxide semiconductor stack overlapping with the gate electrode layer with the gate insulating layer interposed therebetween, and source and drain electrode layers electrically connected to the oxide semiconductor stack. The oxide semiconductor stack includes a first oxide semiconductor layer in contact with the gate insulating layer, a second oxide semiconductor layer over the first oxide semiconductor layer, and a third oxide semiconductor layer over the second oxide semiconductor layer. The first oxide semiconductor layer and the third oxide semiconductor layer each contain indium and zinc as constituent elements and have a larger energy gap than the second oxide semiconductor layer. The second oxide semiconductor layer is an indium zinc oxide layer including a crystalline portion.

In the above-described semiconductor device, the second oxide semiconductor layer preferably contains a larger amount of indium than the third oxide semiconductor layer.

Further, in the above-described semiconductor device, the second oxide semiconductor layer preferably contains a larger amount of indium than the first oxide semiconductor layer.

Further, in the above-described semiconductor device, at least one of the first oxide semiconductor layer and the third oxide semiconductor layer preferably contain one or more metal elements selected from gallium, magnesium, tin, hafnium, aluminum, zirconium, lanthanum, cerium, praseodymium, neodymium, samarium, europium, gadolinium, terbium, dysprosium, holmium, erbium, thulium, ytterbium, and lutetium.

Further, in the above-described semiconductor device, the first oxide semiconductor layer may contain a constituent element of the gate insulating layer as an impurity.

Further, it is preferable that in the crystalline portion in the indium zinc oxide layer in the above-described semiconductor device, a c-axis be aligned with the direction parallel to a normal vector of a surface where the indium zinc oxide layer is formed or a normal vector of a surface of the indium zinc oxide layer, that triangular or hexagonal atomic arrangement which is seen from the direction perpendicular to the a-b plane be formed, and that metal atoms be arranged in a layered manner or metal atoms and oxygen atoms be arranged in a layered manner when seen from the direction perpendicular to the c-axis.

Effects of the structure of one embodiment of the present invention can be described as follow. Note that the description given below is just a consideration.

The transistor of one embodiment of the present invention includes at least the first oxide semiconductor layer in contact with the gate insulating layer and the indium zinc oxide layer including the crystalline portion, which is the second oxide semiconductor layer serving as a current path (channel) of the transistor. Here, the first oxide semiconductor layer serves as a buffer layer for preventing a constituent element of the gate insulating layer from diffusing into the channel. By providing the first oxide semiconductor layer, it is possible to prevent the constituent element from diffusing into an interface between the first oxide semiconductor layer and the second oxide semiconductor layer and into the second oxide semiconductor layer.

The indium zinc oxide layer including the crystalline portion is used as the second oxide semiconductor layer. The first oxide semiconductor layer is an oxide semiconductor layer containing, as well as indium and zinc, a metal element other than indium and zinc as a stabilizer. As the proportion of indium to the other metal elements becomes higher in a metal oxide included in the oxide semiconductor layer, the field-effect mobility of the metal oxide increases; as the proportion of a stabilizer (e.g., gallium) to the other metal elements becomes higher, the energy gap of the metal oxide increases. In one embodiment of the present invention, the first oxide semiconductor layer is an oxide semiconductor layer including a stabilizer, and the second oxide semiconductor layer is an indium zinc oxide layer; thus, the energy gap (band gap) of the first oxide semiconductor layer can be larger than the energy gap of the second oxide semiconductor layer.

In that case, the energy level at the bottom of the conduction band of the indium zinc oxide layer, which is the second oxide semiconductor layer, is lower than the energy level at the bottom of the conduction band of the first oxide semiconductor layer, resulting in a difference in energy at the bottom of the conduction band between the two layers. When such an energy difference exists between the stacked oxide semiconductor layers, carriers flow through the second oxide semiconductor layer without passing through the first oxide semiconductor layer. In other words, a structure where carriers flow through a region which is apart from the gate insulating layer (i.e., buried channel structure) is formed, which can reduce influence of a trap level at an interface on the gate insulating layer side. Thus, photodegradation (e.g., negative-bias temperature stress photodegradation) of the transistor can be reduced, and the transistor can have higher reliability.

Further, the indium zinc oxide layer where the proportion of indium is high is used as the channel, so that the transistor can have high field-effect mobility.

An oxide semiconductor represented by InₐM1_{b}Zn_{c}Oₓ (a: a real number greater than or equal to 0 and less than or equal to 2, b: a real number greater than 0 and less than or equal to 5, c: a real number greater than or equal to 0 and less than or equal to 5, and x: a given real number) can be used for the first oxide semiconductor layer. In addition, M1, which is a stabilizer for stabilizing the electrical characteristics of the transistor, is one or more metal elements selected from Ga, Mg, Hf, Al, Sn, Zr, La, Ce, Pr, Nd, Sm, Eu, Gd, Tb, Dy, Ho, Er, Tm, Yb, and Lu.

It is preferable that the transistor of one embodiment of the present invention further include, as well as the first oxide semiconductor layer and the second oxide semiconductor layer, a third oxide semiconductor layer which is over the second oxide semiconductor layer and is in contact with the source electrode layer and the drain electrode layer. The third oxide semiconductor layer can serve as a buffer layer for preventing a constituent element of the source and drain electrode layers from diffusing into the channel.

Like the first oxide semiconductor layer, the third oxide semiconductor layer is formed of an oxide semiconductor layer including, as a stabilizer, a metal element other than indium and zinc. Thus, the third oxide semiconductor layer has a larger energy gap than the second oxide semiconductor layer. In other words, since a difference in energy at the bottom of the conduction band can be formed between the indium zinc oxide layer, which is the second oxide semiconductor layer, and the third oxide semiconductor layer, carriers flows through the second oxide semiconductor layer without passing through the third oxide semiconductor layer. Thus, even in the case where a trap level due to diffusion of a metal element included in the source and drain electrode layers, or the like exists on the back channel side, the third oxide semiconductor layer provided can reduce influence of the trap level and stabilizes the electrical characteristics of the transistor.

An oxide semiconductor represented by In_{d}M3ₑZn_{f}Oₓ (d: a real number greater than or equal to 0 and less than or equal to 2, e: a real number greater than 0 and less than or equal to 5, f: real number greater than or equal to 0 and less than or equal to 5, and x: a given real number) can be used for the third oxide semiconductor layer. In addition, M3, which is a stabilizer for stabilizing the electrical characteristics of the transistor, is one or more metal elements selected from Ga, Mg, Hf, Al, Sn, Zr, La, Ce, Pr, Nd, Sm, Eu, Gd, Tb, Dy, Ho, Er, Tm, Yb, and Lu.

Note that for a larger energy gap of the first and third oxide semiconductor layers serving as buffer layer, the first oxide semiconductor layer and the third oxide semiconductor layer preferably contains a smaller amount of indium than the indium zinc oxide layer, which is used as the second oxide semiconductor layer and more preferably, the amount of indium is smaller than that of the stabilizer.

A structure of an oxide semiconductor layer which can be used for the semiconductor device is described below.

An oxide semiconductor layer is classified roughly into a single-crystal oxide semiconductor layer and a non-single-crystal oxide semiconductor layer. The non-single-crystal oxide semiconductor layer includes any of an amorphous oxide semiconductor layer, a microcrystalline oxide semiconductor layer, a polycrystalline oxide semiconductor layer, a c-axis aligned crystalline oxide semiconductor (CAAC-OS) film, and the like.

The amorphous oxide semiconductor layer has disordered atomic arrangement and no crystalline component. A typical example thereof is an oxide semiconductor layer in which no crystal part exists even in a microscopic region, and the whole of the film is amorphous.

The microcrystalline oxide semiconductor layer includes a microcrystal (also referred to as nanocrystal) with a size greater than or equal to 1 nm and less than 10 nm, for example. Thus, the microcrystalline oxide semiconductor layer has a higher degree of atomic order than the amorphous oxide semiconductor layer. Hence, the density of defect states of the microcrystalline oxide semiconductor layer is lower than that of the amorphous oxide semiconductor layer.

The CAAC-OS film is one of oxide semiconductor layers including a plurality of crystal parts, and most of the crystal parts each fits inside a cube whose one side is less than 100 nm. Thus, there is a case where a crystal part included in the CAAC-OS film fits a cube whose one side is less than 10 nm, less than 5 nm, or less than 3 nm. The density of defect states of the CAAC-OS film is lower than that of the microcrystalline oxide semiconductor layer. The CAAC-OS film is described in detail below.

In a transmission electron microscope (TEM) image of the CAAC-OS film, a boundary between crystal parts, that is, a grain boundary is not clearly observed. Thus, in the CAAC-OS film, a reduction in electron mobility due to the grain boundary is less likely to occur.

According to the TEM image of the CAAC-OS film observed in a direction substantially parallel to a sample surface (cross-sectional TEM image), metal atoms are arranged in a layered manner in the crystal parts. Each metal atom layer has a morphology reflected by a surface over which the CAAC-OS film is formed (hereinafter, a surface over which the CAAC-OS film is formed is referred to as a formation surface) or a top surface of the CAAC-OS film, and is arranged in parallel to the formation surface or the top surface of the CAAC-OS film.

On the other hand, according to the TEM image of the CAAC-OS film observed in a direction substantially perpendicular to the sample surface (plan TEM image), metal atoms are arranged in a triangular or hexagonal configuration in the crystal parts. However, there is no regularity of arrangement of metal atoms between different crystal parts.

From the results of the cross-sectional TEM image and the plan TEM image, alignment is found in the crystal parts in the CAAC-OS film.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction perpendicular to the c-axis, a peak appears frequently when 2θ is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single-crystal oxide semiconductor layer of InGaZnO₄, six peaks appear. The six peaks are derived from crystal planes equivalent to the (110) plane. On the other hand, in the case of a CAAC-OS film, a peak is not clearly observed even when φ scan is performed with 2θ fixed at around 56°.

According to the above results, in the CAAC-OS film having c-axis alignment, while the directions of a-axes and b-axes are different between crystal parts, the c-axes are aligned in a direction parallel to a normal vector of a formation surface or a normal vector of a top surface. Thus, each metal atom layer arranged in a layered manner observed in the cross-sectional TEM image corresponds to a plane parallel to the a-b plane of the crystal.

Note that the crystal part is formed concurrently with deposition of the CAAC-OS film or is formed through crystallization treatment such as heat treatment. As described above, the c-axis of the crystal is aligned with a direction parallel to a normal vector of a formation surface or a normal vector of a top surface of the CAAC-OS film. Thus, for example, in the case where a shape of the CAAC-OS film is changed by etching or the like, the c-axis might not be necessarily parallel to a normal vector of a formation surface or a normal vector of a top surface of the CAAC-OS film.

Further, the degree of crystallinity in the CAAC-OS film is not necessarily uniform. For example, in the case where crystal growth leading to the CAAC-OS film occurs from the vicinity of the top surface of the film, the degree of the crystallinity in the vicinity of the top surface is higher than that in the vicinity of the formation surface in some cases. Further, when an impurity is added to the CAAC-OS film, the crystallinity in a region to which the impurity is added is changed, and the degree of crystallinity in the CAAC-OS film varies depends on regions.

Note that when the CAAC-OS film with an InGaZnO₄ crystal is analyzed by an out-of-plane method, a peak of 2θ may also be observed at around 36°, in addition to the peak of 2 θ at around 31°. The peak of 2 θ at around 36° indicates that a crystal having no c-axis alignment is included in part of the CAAC-OS film. It is preferable that a peak of 2θ appear at around 31° and a peak of 2θ do not appear at around 36° in the CAAC-OS film.

With the use of the CAAC-OS film in a transistor, change in electrical characteristics of the transistor due to irradiation with visible light or ultraviolet light is small. Thus, the transistor has high reliability.

Note that, in one embodiment of the present invention, the first to third oxide semiconductor layers included in the semiconductor device may be a stacked film including two or more of an amorphous oxide semiconductor layer, a microcrystalline oxide semiconductor layer, and a CAAC-OS film, for example.

In one embodiment of the present invention, an oxide semiconductor layer including a crystalline portion is used as the second oxide semiconductor layer serving as a channel of the transistor. In particular, a CAAC-OS film is preferably used as the second oxide semiconductor layer.

According to one embodiment of the present invention, variations in electrical characteristics of a transistor including an oxide semiconductor can be suppressed, and a highly reliable semiconductor device can be provided.

Further, according to one embodiment of the present invention, high field-effect mobility of a transistor including an oxide semiconductor can be achieved.

### BRIEF DESCRIPTION OF THE DRAWINGS

FIGS. 1A to 1C are a plan view and cross-sectional views illustrating one embodiment of a semiconductor device.

FIGS. 2A to 2C are a plan view and cross-sectional views illustrating one embodiment of a semiconductor device.

FIGS. 3A to 3D are views illustrating an example of a method for manufacturing a semiconductor device.

FIGS. 4A to 4C each illustrate one embodiment of a semiconductor device.

FIGS. 5A and 5B each illustrate one embodiment of a semiconductor device.

FIGS. 6A and 6B illustrate one embodiment of a semiconductor device.

FIGS. 7A and 7B illustrate one embodiment of a semiconductor device.

FIGS. 8A to 8C illustrate electronic appliances.

FIGS. 9A to 9C illustrate an electronic appliance.

FIGS. 10A to 10D are cross-sectional views each illustrating one embodiment of a semiconductor device.

FIG. 11 illustrates one embodiment of a semiconductor device.

FIG. 12 illustrates a deposition apparatus which can be employed for manufacture of a semiconductor device.

FIGS. 13A to 13E are TEM images of samples manufactured in Example.

FIG. 14 shows measurement results of XRD spectra of the samples manufactured in Example.

FIG. 15 shows measurement results of XRD spectra of the samples manufactured in Example.

### DETAILED DESCRIPTION OF THE INVENTION

Hereinafter, embodiments of the present invention will be described in detail with reference to the accompanying drawings. Note that the present invention is not limited to the description below and it is easily understood by those skilled in the art that the mode and details of the present invention can be changed in various ways. Therefore, the invention should not be construed as being limited to the description in the following embodiments.

Note that in structures of the present invention described below, the same portions or portions having similar functions are denoted by the same reference numerals in different drawings, and description thereof is not repeated. Further, the same hatching pattern is applied to portions having similar functions, and the portions are not especially denoted by reference numerals in some cases.

Note that in each drawing described in this specification, the size, the film thickness, or the region of each component is exaggerated for clarity. Therefore, embodiments of the present invention are not limited to such scales.

Note that ordinal numbers such as “first” and “second” in this specification and the like are used for convenience and do not denote the order of steps or the stacking order of layers. In addition, the ordinal numbers in this specification and the like do not denote any particular names to define the invention.

In this specification, a term “parallel” indicates that the angle formed between two straight lines is greater than or equal to −10° and less than or equal to 10°, and accordingly also includes the case where the angle is greater than or equal to −5° and less than or equal to 5°. In addition, a term “perpendicular” indicates that the angle formed between two straight lines is greater than or equal to 80° and less than or equal to 100°, and accordingly includes the case where the angle is greater than or equal to 85° and less than or equal to 95°.

In this specification, the trigonal and rhombohedral crystal systems are included in the hexagonal crystal system.

### Embodiment 1

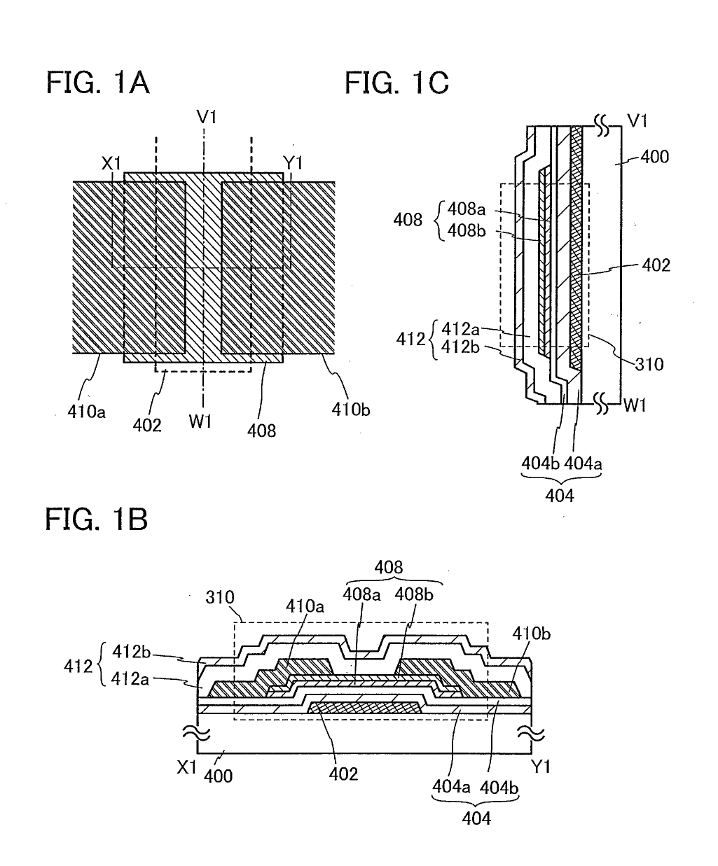

In this embodiment, one embodiment of a semiconductor device and a method for manufacturing the semiconductor device is described with reference to FIGS. 1A to 1C, FIGS. 2A to 2C, FIGS. 3A to 3D, and FIGS. 10A to 10D.

### Structural Example 1 of Semiconductor Device

FIGS. 1A to 1C illustrate a structural example of a transistor 310. FIG. 1A is a plan view of the transistor 310, FIG. 1B is a cross-sectional view taken along dashed-dotted X1-Y1 in FIG. 1A, and FIG. 1C is a cross-sectional view taken along dashed-dotted V1-W1 in FIG. 1A.

The transistor 310 includes a gate electrode layer 402 over a substrate 400 having an insulating surface, a gate insulating layer 404 over the gate electrode layer 402, an oxide semiconductor stack 408 which is on and in contact with the gate insulating layer 404 and overlaps with the gate electrode layer 402, and a source electrode layer 410a and a drain electrode layer 410b which are electrically connected to the oxide semiconductor stack 408. Note that an insulating layer 412 which covers the source electrode layer 410a and the drain electrode layer 410b and is in contact with the oxide semiconductor stack 408 may be included in the transistor 310 as a component. The channel length of the transistor 310 can be, for example, 1 μm or more.

In this embodiment, the gate insulating layer 404 has a stacked structure of a gate insulating layer 404a which is in contact with the gate electrode layer 402 and a gate insulating layer 404b which is provided over the gate insulating layer 404a and is in contact with the oxide semiconductor stack 408. The insulating layer 412 has a stacked structure of an insulating layer 412a in contact with the source electrode layer 410a and the drain electrode layer 410b and an insulating layer 412b over the insulating layer 412a.

In the transistor 310, the oxide semiconductor stack 408 includes a first oxide semiconductor layer 408a in contact with the gate insulating layer 404 and a second oxide semiconductor layer 408b on and in contact with the first oxide semiconductor layer 408a.

In the transistor of one embodiment of the present invention, an indium zinc oxide layer is used as the second oxide semiconductor layer 408b serving as a channel. As described above, as the proportion of indium to the other metal elements becomes higher in a metal oxide, the field-effect mobility of the metal oxide increases; thus, when the second oxide semiconductor layer 408b is formed using an indium zinc oxide, the transistor 310 can have high field-effect mobility. In addition, zinc is preferably included in the metal oxide, in which case an oxide semiconductor layer to be formed can be a CAAC-OS film relatively easily.

An oxide semiconductor layer including a stabilizer is used as the first oxide semiconductor layer 408a so that the energy level at the bottom of the conduction band of the indium zinc oxide layer, which is the second oxide semiconductor layer 408b, is lower than the energy level at the bottom of the conduction band of the first oxide semiconductor layer 408a to make a difference in energy at the bottom of the conduction band. As described above, as the proportion of a stabilizer to the other metal elements (here, indium and zinc) becomes higher than in a metal oxide, the energy gap of the metal oxide increases. Thus, when the first oxide semiconductor layer 408a includes the stabilizer, the energy gap of the first oxide semiconductor layer 408a can be larger than the energy gap of the second oxide semiconductor layer 408b, which does not include a stabilizer, so that a difference in energy level at the bottom of the conduction band can be made.

When there is a difference in energy at the bottom of the conduction band between the first oxide semiconductor layer 408a and the second oxide semiconductor layer 408b serving as a channel, a structure where carriers flow through a region apart from the gate insulating layer 404 in contact with the oxide semiconductor stack 408 can be obtained (i.e., buried channel structure).

The second oxide semiconductor layer 408b serves as a buried channel, so that carrier scattering at an interface can be reduced. As a result, high field-effect mobility can be obtained.

Further, when the first oxide semiconductor layer 408a is provided between the channel and the gate insulating layer, carriers can be prevented from being captured at an interface between the channel and the gate insulating layer, so that photodegradation (e.g., negative-bias temperature stress degradation) of a transistor can be reduced. As a result, the transistor can have high reliability.

As the stabilizer included in the first oxide semiconductor layer 408a, one or more metal elements selected from gallium, magnesium, tin, hafnium, aluminum, zirconium, lanthanum, cerium, praseodymium, neodymium, samarium, europium, gadolinium, terbium, dysprosium, holmium, erbium, thulium, ytterbium, and lutetium.

Note that in general, an oxide semiconductor layer is mostly formed by a sputtering method. On the other hand, when the oxide semiconductor layer is formed by sputtering, in some cases, an ionized rare gas element (e.g., argon) or an element ejected from a surface of a sputtering target flicks off a constituent element of a film, such as a gate insulating film, on which the oxide semiconductor layer is to be formed. The element flicked off from the film on which the oxide semiconductor layer is to be formed might enter the oxide semiconductor layer and function as an impurity element therein. In particular, a portion of the oxide semiconductor layer, which is in the vicinity of the surface on which the oxide semiconductor layer is formed, might have high concentration of the impurity element. Further, when the impurity element remains in the vicinity of the surface where the oxide semiconductor layer is to be formed, the resistance of the oxide semiconductor layer is increased, which causes the electrical characteristics of the transistor to be lowered.

However, in the transistor 310, since the first oxide semiconductor layer 408a is provided between the gate insulating layer 404 and the second oxide semiconductor layer 408b in which the channel is formed, a constituent element of the gate insulating layer 404 can be prevented from diffusing into the channel. In other words, the first oxide semiconductor layer 408a may contain the constituent element (e.g., silicon) of the gate insulating layer 404 as an impurity. By including the first oxide semiconductor layer 408a, the transistor 310 can have more stabilized electrical characteristics; thus, a highly reliable semiconductor device can be provided.

Note that in the case where the first oxide semiconductor layer 408a contains silicon as an impurity, the energy gap of the first oxide semiconductor layer 408a becomes larger.

The thickness of the first oxide semiconductor layer 408a, which reduces influence of a trap level at the interface on the channel side and stabilizes the electrical characteristics of the transistor, is preferably greater than or equal to 3 nm and less than or equal to 20 nm, more preferably greater than or equal to 5 nm and less than or equal to 10 nm. Even when the first oxide semiconductor layer 408a contains the constituent element of the gate insulating layer 404 as an impurity, the thickness of the first oxide semiconductor layer 408a in the above-described ranges can prevent the impurity from reaching the second oxide semiconductor layer 408b serving as a channel. The thickness of the second oxide semiconductor layer 408b serving as a channel is preferably greater than or equal to 10 nm and less than or equal to 40 nm, more preferably greater than or equal to 15 nm and less than or equal to 30 nm

### Structural Example 2 of Semiconductor Device

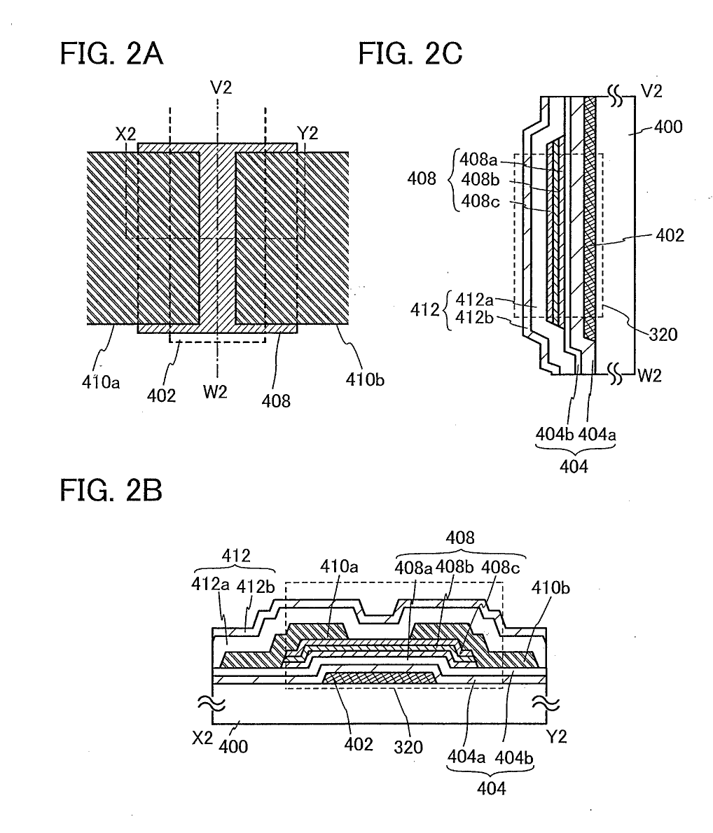

FIGS. 2A to 2C illustrate a structural example of a transistor 320, which is different from the structure illustrated in FIGS. 1A to 1C. FIG. 2A is a plan view of the transistor 320, FIG. 2B is a cross-sectional view taken along dashed-dotted line X2-Y2 in FIG. 2A, and FIG. 2C is a cross-sectional view taken along dashed-dotted line V2-W2 in FIG. 2A.

Like the transistor 310 illustrated in FIGS. 1A to 1C, the transistor 320 illustrated in FIGS. 2A to 2C includes the gate electrode layer 402 over the substrate 400 having an insulating surface, the gate insulating layer 404 over the gate electrode layer 402, the oxide semiconductor stack 408 which is in contact with the gate insulating layer 404 and overlaps with the gate electrode layer 402, and the source electrode layer 410a and the drain electrode layer 410b which are electrically connected to the oxide semiconductor stack 408. Further, the insulating layer 412 which covers the source electrode layer 410a and the drain electrode layer 410b and is in contact with the oxide semiconductor stack 408 may be included in the transistor 320 as a component.

The transistor 320 is different from the transistor 310 in that a third oxide semiconductor layer 408c is provided between the second oxide semiconductor layer 408b, and the source electrode layer 410a and the drain electrode layer 410b. In other words, in the transistor 320, the oxide semiconductor stack 408 has a stacked structure of the first oxide semiconductor layer 408a, the second oxide semiconductor layer 408b, and the third oxide semiconductor layer 408c.

The transistor 320 has the same structure as the transistor 310 except the third oxide semiconductor layer 408c; therefore, the description of the transistor 310 can be referred to.

As the third oxide semiconductor layer 408c, an oxide semiconductor layer which contains, as well as indium and zinc, a stabilizer for stabilizing the electrical characteristics of an oxide semiconductor layer is used. When the third oxide semiconductor layer 408c includes the stabilizer, the energy gap of the third oxide semiconductor layer 408c can be larger than the energy gap of the second oxide semiconductor layer 408b, which does not include a stabilizer, so that a difference in energy level at the bottom of the conduction band can be made between the two layers. Specifically, the energy level at the bottom of the conduction band of the indium zinc oxide layer, which is the second oxide semiconductor layer 408b, can be lower than the energy level at the bottom of the conduction band of the third oxide semiconductor layer 408c. At this time, carriers flow through the second oxide semiconductor layer 408b without passing through the third oxide semiconductor layer 408c.

The third oxide semiconductor layer 408c provided on the back channel side of the second oxide semiconductor layer 408b can reduce influence of a trap level at an interface on the back channel side. For example, the third oxide semiconductor layer 408c can prevent a constituent element of the source electrode layer 410a and the drain electrode layer 410b from diffusing into the second oxide semiconductor layer 408b. In this case, the third oxide semiconductor layer 408c contains the constituent element (e.g., copper) of the source electrode layer 410a and the drain electrode layer 410b as an impurity.

The third oxide semiconductor layer 408c provided can prevent a trap level from being formed in the channel of the transistor; thus, an increase in S value due to the trap level can be suppressed and/or the threshold voltage can be controlled. The threshold voltage is controlled by the third oxide semiconductor layer 408c, so that the transistor can be normally-off.

The thickness of the third oxide semiconductor layer 408c is preferably greater than or equal to 10 nm and less than or equal to 40 nm, more preferably greater than or equal to 15 nm and less than or equal to 30 nm.

In the oxide semiconductor stack included in the transistor of one embodiment of the present invention, the first and third oxide semiconductor layers may have either an amorphous structure or a crystalline structure. Note that the second oxide semiconductor layer serving as a channel is an oxide semiconductor layer including a crystalline portion and is preferably a CAAC-OS film. When the second oxide semiconductor layer 408b is a CAAC-OS film, the density of states (DOS) attributed to an oxygen vacancy in the second oxide semiconductor layer 408b can be reduced.

Further, in the case where the second oxide semiconductor layer 408b and the third oxide semiconductor layer 408c formed on and in contact with the second oxide semiconductor layer 408b are both CAAC-OS films, the crystal structure is preferably continuous between the second oxide semiconductor layer 408b and the third oxide semiconductor layer 408c for the reason described below. When the crystal structure of the third oxide semiconductor layer 408c is continuous with the crystal structure of the second oxide semiconductor layer 408b, DOS is less likely to be formed at the interface between the two layers.

When the third oxide semiconductor layer 408c provided on the back channel side is formed of an amorphous oxide semiconductor, the third oxide semiconductor layer 408c is likely to have oxygen vacancies and easily becomes n-type by etching treatment for forming the source electrode layer 410a and the drain electrode layer 410b. For such a reason, the third oxide semiconductor layer 408c is preferably an oxide semiconductor including a crystalline portion.

Note that when the first oxide semiconductor layer 408a in contact with the gate insulating layer 404 contains the constituent element of the gate insulating layer 404 as an impurity, the crystallinity of the first oxide semiconductor layer 408a is reduced in some cases. In view of the above, the thickness of the first oxide semiconductor layer 408a is made to be greater than or equal to 3 nm and less than or equal to 20 nm, preferably greater than or equal to 5 nm and less than or equal to 10 nm, whereby even when the crystallinity of part of the first oxide semiconductor layer 408a is lowered because of the impurity, the influence thereof on the second oxide semiconductor layer 408b can be reduced. As a result, the second oxide semiconductor layer 408b can be made to be a CAAC-OS film from an interface with the first oxide semiconductor layer 408a.

### Example of Method for Manufacturing Semiconductor Device

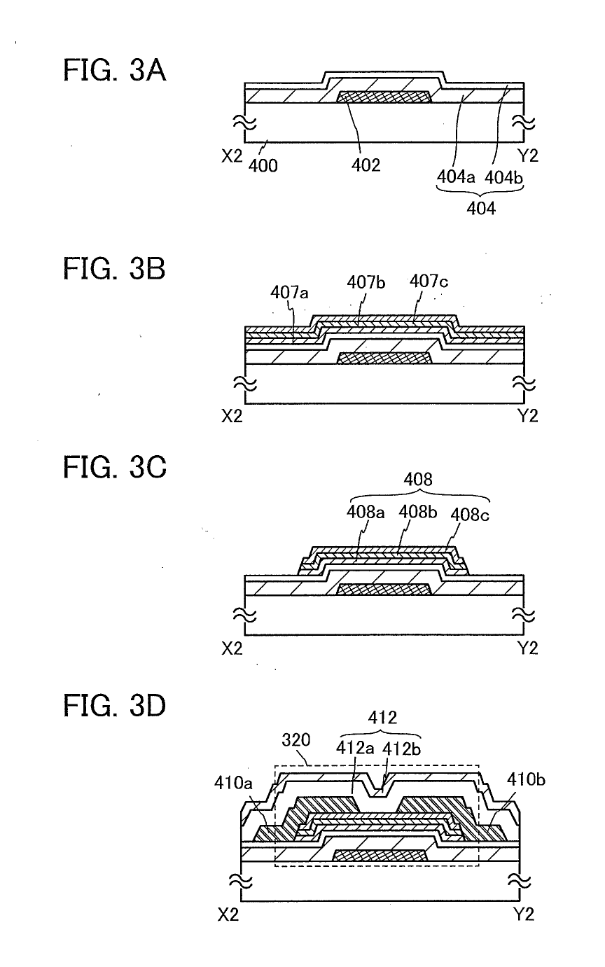

An example of a method for manufacturing the transistor 320 is described below with reference to FIGS. 3A to 3D.

First, the gate electrode layer 402 (including a wiring formed with the same layer) is formed over the substrate 400 having an insulating surface.

There is no particular limitation on the substrate that can be used as the substrate 400 having an insulating surface as long as it has heat resistance high enough to withstand heat treatment performed later. For example, a glass substrate of barium borosilicate glass, aluminoborosilicate glass, or the like, a ceramic substrate, a quartz substrate, or a sapphire substrate can be used. Alternatively, a single crystal semiconductor substrate or a polycrystalline semiconductor substrate made of silicon, silicon carbide, or the like, a compound semiconductor substrate made of silicon germanium or the like, an SOI substrate, or the like may be used as the substrate 400. Still alternatively, any of these substrates further provided with a semiconductor element may be used as the substrate 400. Further alternatively, a base insulating layer may be formed over the substrate 400.

The gate electrode layer 402 can be formed using a metal material such as molybdenum, titanium, tantalum, tungsten, aluminum, copper, chromium, neodymium, or scandium, or an alloy material containing any of these materials as a main component. Alternatively, a semiconductor film typified by a polycrystalline silicon film doped with an impurity element such as phosphorus, or a silicide film such as a nickel silicide film may be used as the gate electrode layer 402. The gate electrode layer 402 may have either a single-layer structure or a stacked-layer structure. The gate electrode layer 402 may have a tapered shape with a taper angle of greater than or equal to 15° and less than or equal to 70° for example. The taper angle here refers to an angle formed by the side surface of a layer which has a tapered shape and the bottom surface of the layer.

The material of the gate electrode layer 402 may be a conductive material such as indium oxide-tin oxide, indium oxide containing tungsten oxide, indium zinc oxide containing tungsten oxide, indium oxide containing titanium oxide, indium tin oxide containing titanium oxide, indium oxide-zinc oxide, or indium tin oxide to which silicon oxide is added.

Alternatively, as the material of the gate electrode layer 402, an In—Ga—Zn-based oxide containing nitrogen, an In—Sn-based oxide containing nitrogen, an In—Ga-based oxide containing nitrogen, an In—Zn-based oxide containing nitrogen, an Sn-based oxide containing nitrogen, an In-based oxide containing nitrogen, or a metal nitride film (such as an indium nitride film, a zinc nitride film, a tantalum nitride film, or a tungsten nitride film) may be used. These materials have a work function of 5 eV or more. Therefore, when the gate electrode layer 402 is formed using any of these materials, the threshold voltage of the transistor can be positive, so that the transistor can be a normally-off switching transistor.

Next, the gate insulating layer 404 is formed so as to cover the gate electrode layer 402 (see FIG. 3A). As the gate insulating layer 404, a single layer or a stack of layers including at least one of the following films formed by a plasma CVD method, a sputtering method, or the like is used: a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film.

Note that a region which is included in the gate insulating layer 404 and is in contact with the first oxide semiconductor layer 408a formed later (in this embodiment, the region is the gate insulating layer 404b) is preferably an oxide insulating layer and preferably includes a region containing oxygen in excess of the stoichiometric composition (i.e., oxygen-excess region). In order to provide the oxygen-excess region in the gate insulating layer 404, for example, the gate insulating layer 404 may be formed in an oxygen atmosphere. Alternatively, oxygen may be introduced into the formed gate insulating layer 404 to provide the oxygen-excess region. As a method for introducing oxygen, an ion implantation method, an ion doping method, a plasma immersion ion implantation method, plasma treatment, or the like may be employed.

In this embodiment, a silicon nitride film is formed as the gate insulating layer 404a and a silicon oxide film is formed as the gate insulating layer 404b.

Next, an oxide semiconductor film 407a, an oxide semiconductor film 407b, and an oxide semiconductor film 407c to be included in the oxide semiconductor stack 408 are sequentially formed over the gate insulating layer 404 (see FIG. 3B).

The oxide semiconductor film 407a which is to be the first oxide semiconductor layer 408a and the oxide semiconductor film 407c which is to be the third oxide semiconductor layer 408c are each formed of an oxide semiconductor film including a stabilizer. As an oxide semiconductor included in the oxide semiconductor film 407a and/or the oxide semiconductor film 407c, any of the following can be used, for example: three-component metal oxides such as an In—Ga—Zn-based oxide, an In—Al—Zn-based oxide, an In—Sn—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, and an In—Lu—Zn-based oxide; and four-component metal oxides such as an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, and an In—Hf—Al—Zn-based oxide.

Note that here, for example, an “In—Ga—Zn-based oxide” means an oxide containing In, Ga, and Zn as its main components and there is no limitation on the ratio of In:Ga:Zn. The In—Ga—Zn-based oxide may contain a metal element other than the In, Ga, and Zn.

An indium zinc oxide film is formed as the oxide semiconductor film 407b which is to be the second oxide semiconductor layer 408b.

The second oxide semiconductor layer 408b in the transistor 320 is formed of an oxide semiconductor layer including a crystalline portion. Note that the second oxide semiconductor layer 408b with higher crystallinity may be obtained by performing heat treatment on the formed oxide semiconductor film 407b. The heat treatment for increasing the crystallinity is performed at a temperature of 250° C. or higher and 700° C. or lower, preferably 400° C. or higher, more preferably 500° C. or higher, still more preferably 550° C. or higher. The heat treatment can also serve as another heat treatment in the manufacturing process. A laser irradiation apparatus may be employed for the heat treatment.

The oxide semiconductor films each can be formed by a sputtering method, a molecular beam epitaxy (MBE) method, a CVD method, a pulse laser deposition method, an atomic layer deposition (ALD) method, or the like as appropriate.

In the formation of the oxide semiconductor films 407a to 407c, the concentration of hydrogen to be contained is preferably reduced as much as possible. In order to reduce the hydrogen concentration, for example, in the case where a sputtering method is used for the deposition, a high-purity rare gas (typically, argon) from which impurities such as hydrogen, water, a hydroxyl group, or a hydride have been removed; oxygen; or a mixed gas of oxygen and the rare gas is used as appropriate as an atmosphere gas supplied to a deposition chamber of a sputtering apparatus.

The oxide semiconductor film is formed in such a manner that a sputtering gas from which hydrogen and moisture are removed is introduced into a deposition chamber while moisture remaining in the deposition chamber is removed, whereby the concentration of hydrogen in the deposited oxide semiconductor film can be reduced. In order to remove the residual moisture in the deposition chamber, an entrapment vacuum pump, for example, a cryopump, an ion pump, or a titanium sublimation pump is preferably used. The evacuation unit may be a turbo molecular pump provided with a cold trap. A cryopump has a high capability in removing a hydrogen molecule, a compound containing a hydrogen atom such as water (H₂O) (preferably, also a compound containing a carbon atom), and the like; thus, the impurity concentration in the oxide semiconductor film formed in the deposition chamber which is evacuated with the cryopump can be reduced.

Further, in the case where the oxide semiconductor films 407a and 407c are formed by a sputtering method, the relative density (the fill rate) of a metal oxide target which is used for forming the oxide semiconductor films is greater than or equal to 90% and less than or equal to 100%, preferably greater than or equal to 95% and less than or equal to 99.9%. With the use of the metal oxide target having high relative density, a dense oxide film can be formed.

Note that formation of the oxide semiconductor film while the substrate 400 is kept at high temperatures is also effective in reducing the impurity concentration in the oxide semiconductor film. The heating temperature of the substrate 400 may be higher than or equal to 150° C. and lower than or equal to 450° C.; the substrate temperature is preferably higher than or equal to 200° C. and lower than or equal to 350° C. An oxide semiconductor film is formed while the substrate is heated at a high temperature, whereby the oxide semiconductor film can have a crystalline portion.

The conditions described below are preferably employed for the formation of the CAAC-OS film.

By reducing the amount of impurities entering the CAAC-OS film during the deposition, the crystal state can be prevented from being broken by the impurities. For example, the concentration of impurities (e.g., hydrogen, water, carbon dioxide, or nitrogen) which exist in the deposition chamber may be reduced. Furthermore, the concentration of impurities in a deposition gas may be reduced. Specifically, a deposition gas whose dew point is −80° C. or lower, preferably −100° C. or lower is used.

By increasing the substrate heating temperature during the deposition, migration of a sputtered particle is likely to occur after the sputtered particle is attached to a substrate surface. Specifically, the substrate heating temperature during the deposition is higher than or equal to 100° C. and lower than or equal to 740° C., preferably higher than or equal to 200° C. and lower than or equal to 500° C. By increasing the substrate heating temperature during the deposition, when the flat-plate-like sputtered particle reaches the substrate, migration occurs on the substrate surface, so that a flat plane of the flat-plate-like sputtered particle is attached to the substrate.

Furthermore, it is preferable that the proportion of oxygen in the deposition gas be increased and the power be optimized in order to reduce plasma damage at the deposition. The proportion of oxygen in the deposition gas is 30 vol % or higher, preferably 100 vol %.

Note that the oxide semiconductor films 407a to 407c are preferably formed in succession without exposure to the air. By forming the oxide semiconductor films in succession without exposure to the air, attachment of hydrogen or a hydrogen compound (e.g., adsorption water) onto surfaces of the oxide semiconductor films can be prevented. Thus, the entry of impurities can be prevented. In a similar manner, the gate insulating layer 404 and the oxide semiconductor film 407a are preferably formed in succession without exposure to the air.

Further, heat treatment is preferably performed on the oxide semiconductor films 407a to 407c in order to remove excess hydrogen (including water and a hydroxyl group) (to perform dehydration or dehydrogenation). The temperature of the heat treatment is higher than or equal to 300° C. and lower than or equal to 700° C., or lower than the strain point of the substrate. The heat treatment can be performed under reduced pressure, a nitrogen atmosphere, or the like. Hydrogen, which is an impurity imparting n-type conductivity, can be removed by the heat treatment.

Note that the heat treatment for the dehydration or dehydrogenation may be performed at any timing in the manufacturing process of the transistor as long as it is performed after the formation of the oxide semiconductor film. For example, the heat treatment may be performed after the oxide semiconductor film is processed into an island shape. The heat treatment for dehydration or dehydrogenation may be performed plural times, and may also serve as another heat treatment. A laser irradiation apparatus may be used for the heat treatment.

In the heat treatment, it is preferable that water, hydrogen, or the like be not contained in nitrogen or a rare gas such as helium, neon, or argon. The purity of nitrogen or the rare gas such as helium, neon, or argon which is introduced into the heat treatment apparatus is set to preferably 6N (99.9999%) or higher, further preferably 7N (99.99999%) or higher (that is, the impurity concentration is preferably 1 ppm or lower, further preferably 0.1 ppm or lower).

In addition, after the oxide semiconductor film is heated in the heat treatment, a high-purity oxygen gas, a high-purity dinitrogen monoxide gas, or ultra dry air (the moisture amount is less than or equal to 20 ppm (−55° C. by conversion into a dew point), preferably less than or equal to 1 ppm, further preferably less than or equal to 10 ppb, in the measurement with use of a dew point meter of a cavity ring down laser spectroscopy (CRDS) system) may be introduced into the same furnace while the heating temperature is maintained or slow cooling is performed to lower the temperature from the heating temperature. It is preferable that water, hydrogen, or the like be not contained in the oxygen gas or the dinitrogen monoxide gas. The purity of the oxygen gas or the dinitrogen monoxide gas which is introduced into the heat treatment apparatus is preferably 6N or more, further preferably 7N or more (that is, the impurity concentration in the oxygen gas or the dinitrogen monoxide gas is preferably 1 ppm or lower, further preferably 0.1 ppm or lower). The oxygen gas or the dinitrogen monoxide gas acts to supply oxygen which is a main component of the oxide semiconductor and that has been reduced by the step of removing an impurity for the dehydration or dehydrogenation, so that the oxide semiconductor layer can have high purity and be an i-type (intrinsic) oxide semiconductor layer.

Since there is a possibility that oxygen is also released and reduced by dehydration or dehydrogenation treatment, oxygen (including at least one of an oxygen radical, an oxygen atom, and an oxygen ion) may be introduced into the oxide semiconductor layers which have been subjected to the dehydration or dehydrogenation treatment to supply oxygen to the layers.

Oxygen is added to the dehydrated or dehydrogenated oxide semiconductor film to be supplied thereto, so that the oxide semiconductor film can be highly purified and be i-type (intrinsic). Variations in electrical characteristics of a transistor having the highly-purified and i-type (intrinsic) oxide semiconductor are suppressed, and the transistor is electrically stable.

In the step of introduction of oxygen, oxygen may be directly introduced to the oxide semiconductor film (oxide semiconductor layer) through another insulating layer to be formed later. As a method for introducing oxygen (including at least one of an oxygen radical, an oxygen atom, and an oxygen ion), an ion implantation method, an ion doping method, a plasma immersion ion implantation method, plasma treatment, or the like can be used. A gas containing oxygen can be used for oxygen introduction treatment. As the gas containing oxygen, oxygen, dinitrogen monoxide, nitrogen dioxide, carbon dioxide, carbon monoxide, and the like can be used. Further, a rare gas may be contained in the gas containing oxygen in the oxygen introducing treatment.

For example, in the case where an oxygen ion is implanted by an ion implantation method, the dose can be greater than or equal to 1×10¹³ ions/cm² and less than or equal to 5×10¹⁶ ions/cm².

The timing of supply of oxygen to the oxide semiconductor film is not particularly limited to the above as long as it is after the formation of the oxide semiconductor film. The step of introducing oxygen may be performed plural times.

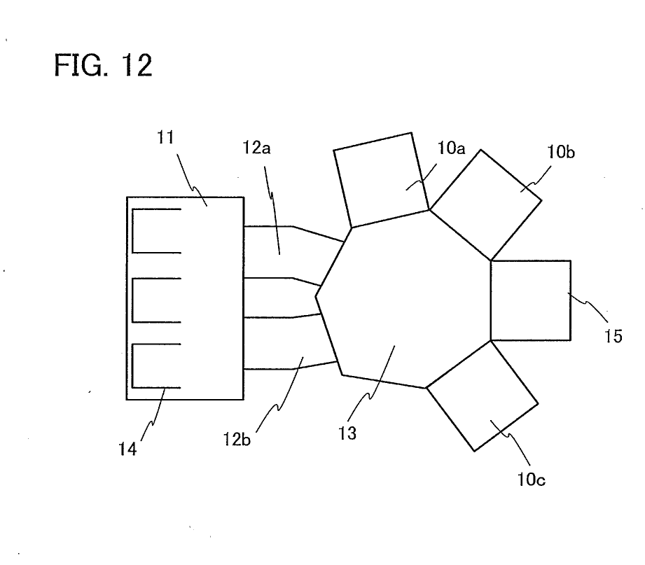

In the case where the oxide semiconductor films 407a to 407c are formed in succession without exposure to the air, a manufacturing apparatus a top view of which is illustrated in FIG. 12 may be employed.

The manufacturing apparatus illustrated in FIG. 12 is single wafer multi-chamber equipment, which includes three sputtering devices 10a, 10b, and 10c, a substrate supply chamber 11 provided with three cassette ports 14 for holding a process substrate, load lock chambers 12a and 12b, a transfer chamber 13, a substrate heating chamber 15, and the like. Note that a transfer robot for transferring a substrate to be treated is provided in each of the substrate supply chamber 11 and the transfer chamber 13. The atmospheres of the sputtering devices 10a, 10b, and 10c, the transfer chamber 13, and the substrate heating chamber 15 are preferably controlled so as to hardly contain hydrogen and moisture (i.e., as an inert atmosphere, a reduced pressure atmosphere, or a dry air atmosphere). For example, a preferable atmosphere is a dry nitrogen atmosphere in which the dew point of moisture is −40° C. or lower, preferably −50° C. or lower. An example of a procedure of the manufacturing steps with use of the manufacturing apparatus illustrated in FIG. 12 is as follows. A process substrate is transferred from the substrate supply chamber 11 to the substrate heating chamber 15 through the load lock chamber 12a and the transfer chamber 13; moisture attached to the process substrate is removed by vacuum baking or the like in the substrate heating chamber 15; the process substrate is transferred to the sputtering device 10c through the transfer chamber 13; and the oxide semiconductor film 407a is formed in the sputtering device 10c. Then, the process substrate is transferred to the sputtering device 10a through the transfer chamber 13 without exposure to the air, and the oxide semiconductor film 407b is formed in the sputtering device 10a. Then, the process substrate is transferred to the sputtering device 10b through the transfer chamber 13 without exposure to the air, and the oxide semiconductor film 407c is formed in the sputtering device 10b. If necessary, the process substrate is transferred to the substrate heating chamber 15 though the transfer chamber 13 without exposure to the air and subjected to heat treatment. As described above, with use of the manufacturing apparatus illustrated in FIG. 12, a manufacturing process can proceed without exposure to air. Further, with of the sputtering devices in the manufacturing apparatus in FIG. 12, a process performed without exposure to the air can be achieved by change of the sputtering target.

Next, the oxide semiconductor films 407a, 407b, and 407c are processed into the island-shaped first oxide semiconductor layer 408a, second oxide semiconductor layer 408b, and third oxide semiconductor layer 408c, respectively, whereby the oxide semiconductor stack 408 is formed (see FIG. 3C).

Note that in this embodiment, the oxide semiconductor films 407a to 407c are processed into island shapes by one etching treatment; thus, the ends of the oxide semiconductor layers included in the oxide semiconductor stack 408 are aligned with each other. Note that in this specification, “aligning with” includes “substantially aligning with”. For example, an end of a layer A and an end of a layer B, which are included in a stacked-layer structure etched using the same mask, are considered to be aligned with each other.

Then, a conductive film is formed over the oxide semiconductor stack 408 and processed to form the source electrode layer 410a and the drain electrode layer 410b (including a wiring formed using the same layer).

The source electrode layer 410a and the drain electrode layer 410b can be formed using, for example, a metal film containing an element selected from Al, Cr, Cu, Ta, Ti, Mo, and W, a metal nitride film containing any of these elements as its component (a titanium nitride film, a molybdenum nitride film, or a tungsten nitride film), or the like. Alternatively, a film of a high-melting-point metal such as Ti, Mo, or W or a metal nitride film of any of these elements (a titanium nitride film, a molybdenum nitride film, or a tungsten nitride film) may be stacked on one of or both a bottom side and a top side of a metal film of Al, Cu, or the like. Further alternatively, the source electrode layer 410a and the drain electrode layer 410b may be formed using a conductive metal oxide. As the conductive metal oxide, indium oxide (In₂O₃), tin oxide (SnO₂), zinc oxide (ZnO), indium oxide-tin oxide (In₂O₃—SnO₂), indium oxide-zinc oxide (In₂O₃—ZnO), or any of these metal oxide materials containing silicon oxide can be used.

For the source electrode layer 410a and the drain electrode layer 410b, a metal nitride film such as an In—Ga—Zn—O film containing nitrogen, an In—Sn—O film containing nitrogen, an In—Ga—O film containing nitrogen, an In—Zn—O film containing nitrogen, a Sn—O film containing nitrogen, or an In—O film containing nitrogen can be used. These films contain the same constituent elements as the oxide semiconductor stack 408 and can therefore stabilize the interface with the oxide semiconductor stack 408.

Next, the insulating layer 412 is formed to cover the source electrode layer 410a, the drain electrode layer 410b, and the exposed oxide semiconductor stack 408 (see FIG. 3D).

The insulating layer 412 can be formed using a single layer or a stack of layers of one or more of the following films formed by a plasma CVD method or a sputtering method: a silicon oxide film, a gallium oxide film, an aluminum oxide film, a silicon nitride film, a silicon oxynitride film, an aluminum oxynitride film, a silicon nitride oxide film, and the like. Note that an oxide insulating layer is preferably formed as the insulating layer 412 (insulating layer 412a in this embodiment) in contact with the oxide semiconductor stack 408, in which case the oxide insulating layer can supply oxygen to the oxide semiconductor stack 408.

For example, a silicon oxide film or a silicon oxynitride film may be formed under the following conditions: the substrate placed in a treatment chamber of a plasma CVD apparatus, which is vacuum-evacuated, is held at a temperature higher than or equal to 180° C. and lower than or equal to 400° C., preferably higher than or equal to 200° C. and lower than or equal to 370° C., the pressure in the treatment chamber is greater than or equal to 30 Pa and less than or equal to 250 Pa, preferably greater than or equal to 40 Pa and less than or equal to 200 Pa with introduction of a source gas into the treatment chamber, and high-frequency power is supplied to an electrode provided in the treatment chamber. Under the above-described conditions, an oxide insulating layer through which oxygen is diffused can be formed.

After the formation of the oxide insulating layer through which oxygen is diffused, a silicon oxide film or a silicon oxynitride film may be formed under the following conditions: the substrate placed in a treatment chamber of the plasma CVD apparatus, which is vacuum-evacuated, without exposure to the air is held at a temperature higher than or equal to 180° C. and lower than or equal to 250° C., preferably higher than or equal to 180° C. and lower than or equal to 230° C., the pressure in the treatment chamber is greater than or equal to 100 Pa and less than or equal to 250 Pa, preferably greater than or equal to 100 Pa and less than or equal to 200 Pa with introduction of a source gas into the treatment chamber, and high-frequency power higher than or equal to 0.17 W/cm² and lower than or equal to 0.5 W/cm², preferably higher than or equal to 0.26 W/cm² and lower than or equal to 0.35 W/cm² is supplied to an electrode provided in the treatment chamber. Under the above conditions, the decomposition efficiency of the source gas in plasma is enhanced, oxygen radicals are increased, and oxidation of the source gas is promoted; thus, the oxygen content in the formed silicon oxide film or silicon oxynitride film is in excess of that in the stoichiometric composition. However, the bonding strength of silicon and oxygen is weak in the above substrate temperature range; therefore, part of oxygen is released by heating. Thus, it is possible to form an oxide insulating layer which contains oxygen in a proportion higher than that of oxygen in the stoichiometric composition and from which part of oxygen is released by heating.

In this embodiment, a stack of the silicon oxide film through which oxygen is diffused and the silicon oxide film from which part of oxygen is released by heating, which are described above, is formed as the insulating layer 412a, and a silicon nitride film is formed as the insulating layer 412b.

In the structure described in this embodiment, oxide insulating layers (specifically, silicon oxide films) are included as the insulating layers (the gate insulating layer 404b and the insulating layer 412a) in contact with the oxide semiconductor stack 408. Thus, oxygen can be supplied to the first oxide semiconductor layer 408a and the third oxide semiconductor layer 408c to fill oxygen vacancies in the oxide semiconductor layers. Further, silicon nitride films are included as the insulating layers (the gate insulating layer 404a and the insulating layer 412b) provided above and below the oxide semiconductor stack 408 to be in contact with the oxide insulating layers. The silicon nitride films can function as blocking films which prevent the entry of hydrogen or a hydrogen compound (e.g., water) into the oxide semiconductor stack 408. Thus, the reliability of a transistor including such a stacked-layer structure can be improved.

Heat treatment may be performed after the insulating layer 412 is formed. The temperature of the heat treatment is typically higher than or equal to 150° C. and lower than the strain point of the substrate, preferably higher than or equal to 200° C. and lower than or equal to 450° C., more preferably higher than or equal to 300° C. and lower than or equal to 450° C.

Through the above-described steps, the transistor 320 of this embodiment can be manufactured.

### Structural Example 3 of Semiconductor Device

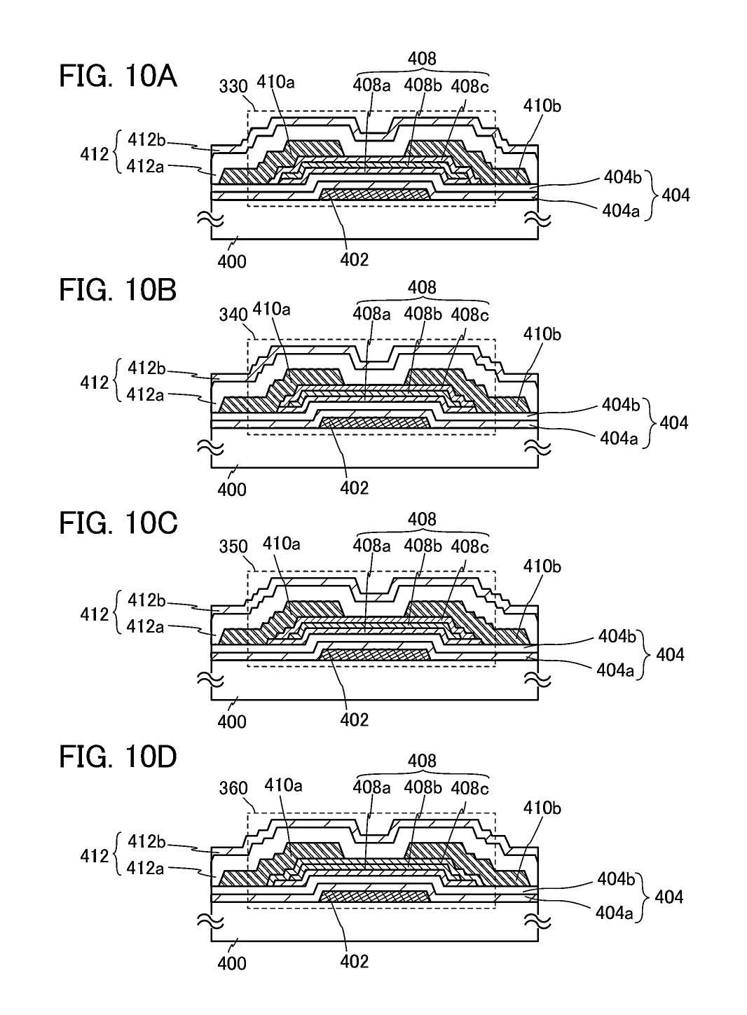

FIG. 10A illustrates a structural example of a transistor 330. Like the transistor 320 illustrated in FIGS. 2A to 2C, the transistor 330 illustrated in FIG. 10A includes the gate electrode layer 402 over the substrate 400 having an insulating surface, the gate insulating layer 404 over the gate electrode layer 402, the oxide semiconductor stack 408 which is in contact with the gate insulating layer 404, overlaps with the gate electrode layer 402, and includes the first oxide semiconductor layer 408a, the second oxide semiconductor layer 408b, and the third oxide semiconductor layer 408c, and the source electrode layer 410a and the drain electrode layer 410b which are electrically connected to the oxide semiconductor stack 408. Further, the insulating layer 412 which covers the source electrode layer 410a and the drain electrode layer 410b and is in contact with the oxide semiconductor stack 408 may be included in the transistor 330 as a component.

The transistor 330 is different from the transistor 320 in that the third oxide semiconductor layer 408c included in the oxide semiconductor stack 408 covers side surfaces of the first oxide semiconductor layer 408a and the second oxide semiconductor layer 408b. In the transistor 330, the periphery of the third oxide semiconductor layer 408c is in contact with the gate insulating layer 404.

Note that the transistor 330 has the same structure as the transistor 320 except the oxide semiconductor stack 408; therefore, the description of the transistor 320 can be referred to.

A method for forming the oxide semiconductor stack 408 included in the transistor 330 is described below. First, the oxide semiconductor film 407a and the oxide semiconductor film 407b are formed as in the step illustrated in FIG. 3B and are processed into island shapes by etching treatment using photolithography, whereby the first oxide semiconductor layer 408a and the second oxide semiconductor layer 408b are formed. After that, the oxide semiconductor film 407c is formed so as to cover the first oxide semiconductor layer 408a and the second oxide semiconductor layer 408b and is processed into an island shape with the use of a mask which is different from that used for processing the first oxide semiconductor layer 408a and the second oxide semiconductor layer 408b, whereby the third oxide semiconductor layer 408c is formed. Through the above steps, the oxide semiconductor stack 408 included in the transistor 330 can be formed.

In the oxide semiconductor stack 408 illustrated in FIG. 10A, the side surface of the second oxide semiconductor layer 408b serving as a channel is covered with the third oxide semiconductor layer 408c so as not to be in contact with the source electrode layer 410a and the drain electrode layer 410b. Such a structure can reduce generation of leakage current between the source electrode layer 410a and the drain electrode layer 410b of the transistor.

### Structural Example 4 of Semiconductor Device

FIG. 10B illustrates a structural example of a transistor 340. The transistor 340 illustrated in FIG. 10B is a modified example of the transistor 330 illustrated in FIG. 10A. In the transistor 340, the third oxide semiconductor layer 408c included in the oxide semiconductor stack 408 covers a side surface and a top surface of the second oxide semiconductor layer 408b, and an end of the first oxide semiconductor layer 408a is aligned with an end of the third oxide semiconductor layer 408c. In the transistor 340, the periphery of the third oxide semiconductor layer 408c is in contact with a top surface of the first oxide semiconductor layer 408a.

Note that the transistor 340 has the same structure as the transistor 330 except the oxide semiconductor stack 408; therefore, the description of the transistor 330 can be referred to.

The oxide semiconductor stack 408 included in the transistor 340 is described below. First, the oxide semiconductor film 407a and the oxide semiconductor film 407b are formed as in the step illustrated in FIG. 3B, and then the oxide semiconductor film 407b is processed into the island-shaped second oxide semiconductor layer 408b by etching treatment using photolithography. After that, the oxide semiconductor film 407c is formed over the oxide semiconductor film 407a so as to cover the second oxide semiconductor layer 408b, and the oxide semiconductor film 407a and the oxide semiconductor film 407c are processed into island shapes with the use of a mask which is different from that used for obtaining the second oxide semiconductor layer 408b, whereby the first oxide semiconductor layer 408a and the third oxide semiconductor layer 408c are formed. Through the above steps, the oxide semiconductor stack 408 included in the transistor 340 can be formed.

Such a structure of the transistor 340 illustrated in FIG. 10B can reduce generation of leakage current between the source electrode layer 410a and the drain electrode layer 410b of the transistor, as in the case of the transistor 330. Further, in the transistor 340, the third oxide semiconductor layer 408c covers a step formed because of the thickness of the second oxide semiconductor layer 408b; the coverage of the end of the second oxide semiconductor layer 408b can be higher than that in the transistor 330 in which the third oxide semiconductor layer 408c covers a step formed because of the thicknesses of both the first oxide semiconductor layer 408a and the second oxide semiconductor layer 408b.

### Structural Example 5 of Semiconductor Device

FIG. 10C illustrates a structural example of a transistor 350. The transistor 350 illustrated in FIG. 10C is a modified example of the transistor 330 illustrated in FIG. 10A. In the transistor 350, the third oxide semiconductor layer 408c included in the oxide semiconductor stack 408 covers a side surface and a top surface of the second oxide semiconductor layer 408b, and the end of the third oxide semiconductor layer 408c is positioned over the first oxide semiconductor layer 408a.

Note that the transistor 350 has the same structure as the transistor 330 except the oxide semiconductor stack 408; therefore, the description of the transistor 330 can be referred to.

A method for forming the oxide semiconductor stack 408 included in the transistor 350 is described below. First, the oxide semiconductor film 407a is formed as in the step illustrated in FIG. 3B and then is processed into the island-shaped first oxide semiconductor layer 408a by etching treatment using photolithography. After that, the oxide semiconductor film 407b is formed so as to cover the first oxide semiconductor layer 408a and is processed into an island shape with the use of a mask which is different from that used for obtaining the first oxide semiconductor layer 408a, whereby the second oxide semiconductor layer 408b is formed. Then, the oxide semiconductor film 407c is formed so as to cover the island-shaped first oxide semiconductor layer 408a and the island-shaped second oxide semiconductor layer 408b and is processed into an island shape with the use of a mask which is different from those used for obtaining the first oxide semiconductor layer 408a and the second oxide semiconductor layer 408b, whereby the third oxide semiconductor layer 408c is formed. Through the above steps, the oxide semiconductor stack 408 included in the transistor 350 can be formed.

Such a structure of the transistor 350 illustrated in FIG. 10C, like the structure of the transistor 340, can reduce generation of leakage current between the source electrode layer 410a and the drain electrode layer 410b and can improve the coverage of the end of the second oxide semiconductor layer 408b. Further, the end of the third oxide semiconductor layer 408c is positioned over the first oxide semiconductor layer 408a, so that the end of the first oxide semiconductor layer 408a is not aligned with the end of the third oxide semiconductor layer 408c and the coverage with a conductive layer which is to be the source electrode layer 410a and the drain electrode layer 410b can be improved.

### Structure Example 6 of Semiconductor Device

FIG. 10D illustrates a structural example of a transistor 360. The transistor 360 illustrated in FIG. 10D is a modified example of the transistor 330 illustrated in FIG. 10A. In the transistor 360, the third oxide semiconductor layer 408c included in the oxide semiconductor stack 408 covers a side surface and a top surface of the second oxide semiconductor layer 408b and a side surface and part of a top surface of the first oxide semiconductor layer 408a.

Note that the transistor 360 has the same structure as the transistor 330 except the oxide semiconductor stack 408; therefore, the description of the transistor 330 can be referred to.

The oxide semiconductor stack 408 included in the transistor 360 is formed by processing the oxide semiconductor films 407a, 407b, and 407c into island shapes with the use of different masks, as in the case of the transistor 350. Note that in the transistor 360, the top surface of the first oxide semiconductor layer 408a is larger than that of the second oxide semiconductor layer 408b, and the top surface of the third oxide semiconductor layer 408c is larger than that of the first oxide semiconductor layer 408a.

Such a structure of the transistor 360 illustrated in FIG. 10D can reduce generation of leakage current between the source electrode layer 410a and the drain electrode layer 410b of the transistor and can improve the coverage of the end of the second oxide semiconductor layer 408b, as in the case of the transistor 340. Further, the side surface of the first oxide semiconductor layer 408a can be protected by the third oxide semiconductor layer 408c.

The structures of the transistors illustrated in FIGS. 1A to 1C, FIGS. 2A to 2C, and FIGS. 10A to 10D are partly different from one another. One embodiment of the present invention is not particularly limited to any of the structures, and a variety of combinations of the structures are possible.

In each of the transistors described in this embodiment, the indium zinc oxide layer including a crystalline portion, which is the second oxide semiconductor layer 408b serving as a current path (channel) of the transistor, is sandwiched between the first oxide semiconductor layer 408a and the third oxide semiconductor layer 408c which include stabilizers and have large energy gaps. This structure enables the channel to be away from an interface between the oxide semiconductor layer and an insulating layer in contact with the oxide semiconductor stack 408, leading to formation of a buried channel structure, so that the field-effect mobility of the transistor can be increased.

Further, this structure prevents formation of a trap level at the interface of the second oxide semiconductor layer 408b serving as the channel, and thus enables the transistor to have high reliability.

The methods, structures, and the like described in this embodiment can be combined as appropriate with any of the methods, structures, and the like described in the other embodiments.

### Embodiment 2

A semiconductor device having a display function (also referred to as a display device) can be manufactured using the transistor described in Embodiment 1. Further, part or all of the driver circuitry which includes the transistor can be formed over a substrate where a pixel portion is formed, whereby a system-on-panel can be formed.

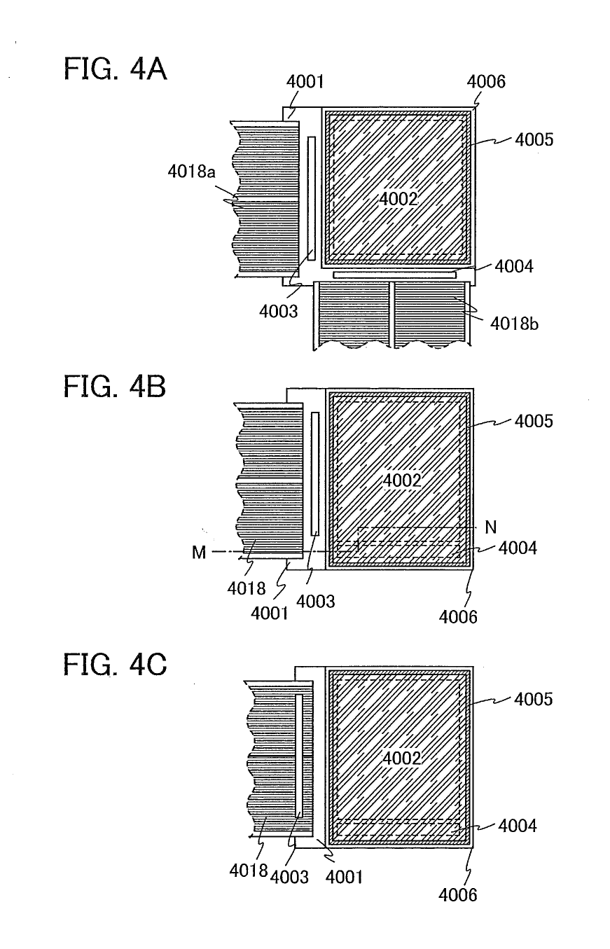

In FIG. 4A, a sealant 4005 is provided so as to surround a pixel portion 4002 provided over a substrate 4001, and the pixel portion 4002 is sealed with a substrate 4006. In FIG. 4A, a scan line driver circuit 4004 and a signal line driver circuit 4003 which are each formed using a single crystal semiconductor film or a polycrystalline semiconductor film over an IC chip or a substrate separately prepared are mounted on the substrate 4001, in a region which is different from the region surrounded by the sealant 4005. Various signals and potentials which are provided to the pixel portion 4002 through the signal line driver circuit 4003 and the scan line driver circuit 4004 are supplied from flexible printed circuits (FPCs) 4018a and 4018b.

In FIGS. 4B and 4C, the sealant 4005 is provided so as to surround the pixel portion 4002 and the scan line driver circuit 4004 which are provided over the substrate 4001. The substrate 4006 is provided over the pixel portion 4002 and the scan line driver circuit 4004. Consequently, the pixel portion 4002 and the scan line driver circuit 4004 are sealed together with a display element by the substrate 4001, the sealant 4005, and the substrate 4006. In FIGS. 4B and 4C, the signal line driver circuit 4003 which is formed using a single crystal semiconductor film or a polycrystalline semiconductor film over an IC chip or a substrate separately prepared is mounted on the substrate 4001, in a region which is different from the region surrounded by the sealant 4005. In FIGS. 4B and 4C, various signals and potentials are supplied to the pixel portion 4002 through the signal line driver circuit 4003 and the scan line driver circuit 4004 from an FPC 4018.

Although FIGS. 4B and 4C each illustrate an example in which the signal line driver circuit 4003 is formed separately and mounted on the substrate 4001, one embodiment of the present invention is not limited to this structure. The scan line driver circuit may be separately formed and then mounted, or only part of the signal line driver circuit or part of the scan line driver circuit may be separately formed and then mounted.

Note that a connection method of a separately formed driver circuit is not particularly limited, and a chip on glass (COG) method, a wire bonding method, a tape automated bonding (TAB) method or the like can be used. FIG. 4A illustrates an example in which the signal line driver circuit 4003 and the scan line driver circuit 4004 are mounted by a COG method. FIG. 4B illustrates an example in which the signal line driver circuit 4003 is mounted by a COG method. FIG. 4C illustrates an example in which the signal line driver circuit 4003 is mounted by a TAB method.

Note that the display device includes a panel in which the display element is sealed, and a module in which an IC including a controller or the like is mounted on the panel. In other words, the display device in this specification means an image display device or a light source (including a lighting device). Furthermore, the display device also includes the following modules in its category: a module to which a connector such as an FPC or a TCP is attached; a module having a TCP at the end of which a printed wiring board is provided; and a module in which an integrated circuit (IC) is directly mounted on a display element by a COG method.

The pixel portion and the scan line driver circuit provided over the substrate include a plurality of transistors, and any of the transistors described in Embodiment 1 can be applied thereto.

As the display element provided in the display device, a liquid crystal element (also referred to as a liquid crystal display element) or a light-emitting element (also referred to as a light-emitting display element) can be used. The light-emitting element includes an element whose luminance is controlled by current or voltage in its category, and specifically includes an inorganic electroluminescent (EL) element, an organic EL element, and the like. Furthermore, a display medium whose contrast is changed by an electric effect, such as an electronic ink display (electronic paper), can be used.

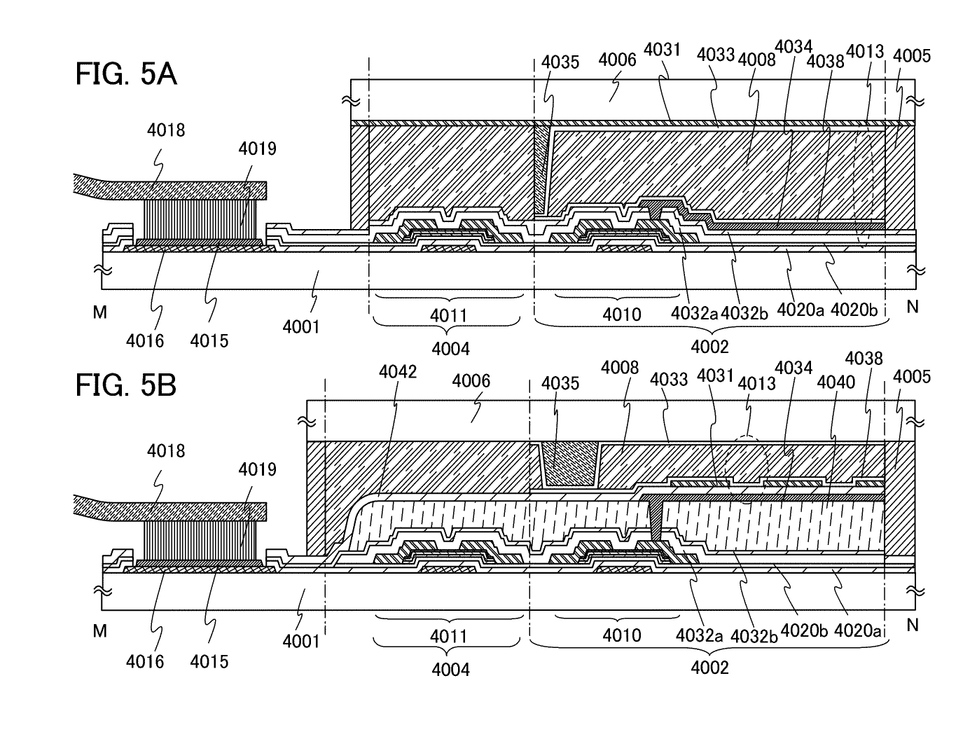

Embodiments of the semiconductor device is described with reference to FIGS. 4A to 4C and FIGS. 5A and 5B. FIGS. 5A and 5B correspond to cross-sectional views along line M-N in FIG. 4B. Examples of a liquid crystal display device using a liquid crystal element as a display element are illustrated in FIGS. 5A and 5B.

A liquid crystal display device can employ a vertical electric field mode or a horizontal electric field mode. FIG. 5A illustrates an example in which a vertical electric field mode is employed, and FIG. 5B illustrates and example in which a fringe field switching (FFS) mode, which is one of the horizontal electric field modes, is employed.

Note that a transistor 4010 provided in the pixel portion 4002 is electrically connected to a display element to form a display panel. A variety of display elements can be used as the display element as long as display can be performed.

As illustrated in FIGS. 4A to 4C and FIGS. 5A and 5B, the semiconductor device includes a connection terminal electrode 4015 and a terminal electrode 4016. The connection terminal electrode 4015 and the terminal electrode 4016 are electrically connected to a terminal included in the FPC 4018 or 4018b through an anisotropic conductive layer 4019.

The connection terminal electrode 4015 is formed from the same conductive layer as a first electrode layer 4034. The terminal electrode 4016 is formed from the same conductive layer as gate electrode layers of the transistor 4010 and a transistor 4011.

The pixel portion 4002 and the scan line driver circuit 4004 provided over the substrate 4001 include a plurality of transistors. FIGS. 5A and 5B illustrate the transistor 4010 included in the pixel portion 4002 and the transistor 4011 included in the scan line driver circuit 4004. In each of FIGS. 5A and 5B, insulating layers 4032a and 4032b are provided over the transistors 4010 and 4011.

In FIG. 5B, a planarization insulating layer 4040 is provided over the insulating layer 4032b, and an insulating layer 4042 is provided between the first electrode layer 4034 and the second electrode layer 4031.

Any of the transistors described in Embodiment 1 can be applied to the transistors 4010 and 4011. In this embodiment, an example in which a transistor having a structure similar to that of the transistor 320 described in Embodiment 1 is used is described. The transistors 4010 and 4011 are bottom-gate transistors.

The transistors 4010 and 4011 each have a stacked structure of gate insulating layers 4020a and 4020b. In FIG. 5A, the gate insulating layers 4020a and 4020b of the transistors 4010 and 4011 and the insulating layers 4032a and 4032b provided over the transistors 4010 and 4011 are extended below the sealant 4005 so as to cover the end of the terminal electrode 4016. In FIG. 5B, the gate insulating layer 4020a and the insulating layer 4032b are extended below the sealant 4005 so as to cover the end of the terminal electrode 4016, and the insulating layer 4032b cover side surfaces of the gate insulating layer 4020b and the insulating layer 4032a.

The transistors 4010 and 4011 each include an indium zinc oxide layer as the second oxide semiconductor layer which serves as a current path (channel) and includes a crystalline portion, and a first oxide semiconductor layer including a stabilizer and a third oxide semiconductor layer between which the second oxide semiconductor layer is sandwiched. Thus, the transistors 4010 and 4011 are each a buried channel transistor in which a current path is positioned away from an interface with the insulating layer, and therefore has high field-effect mobility. In addition, the transistors 4010 and 4011 are each a highly reliable transistor in which influence of an interface state which can be formed on the back channel side is reduced and photodegradation (e.g., negative-bias temperature stress photodegradation) is reduced.

Moreover, a conductive layer may be provided so as to overlap with a channel formation region of the oxide semiconductor layer of the transistor 4011 for the driver circuit. By providing the conductive layer so as to overlap with the channel formation region in the oxide semiconductor layer, the amount of change in the threshold voltage of the transistor 4011 can be further reduced. The conductive layer may have the same potential as or a potential different from that of a gate electrode layer of the transistor 4011, and can function as a second gate electrode layer. The potential of the conductive layer may be, for example, in a floating state.

The conductive layer also functions to block an external electric field, that is, to prevent an external electric field (particularly, to prevent static electricity) from effecting the inside (a circuit portion including a transistor). A blocking function of the conductive layer can suppress variations in the electrical characteristics of the transistor due to an influence of an external electric field such as static electricity.

In FIGS. 5A and 5B, a liquid crystal element 4013 includes a first electrode layer 4034, a second electrode layer 4031, and a liquid crystal layer 4008. Note that insulating layers 4033 and 4038 serving as alignment films are provided so that the liquid crystal layer 4008 is interposed therebetween.

In FIG. 5A, the second electrode layer 4031 is provided on the substrate 4006 side, and the first electrode layer 4034 and the second electrode layer 4031 are stacked with the liquid crystal layer 4008 interposed therebetween. In FIG. 5B, the second electrode layer 4031 having an opening pattern is provided below the liquid crystal layer 4008, and the first electrode layer 4034 having a flat plate shape is provided below the second electrode layer 4031 with the insulating layer 4042 interposed therebetween. In FIG. 5B, the second electrode layer 4031 having an opening pattern includes a bent portion or a comb-shaped portion. The first electrode layer 4034 and the second electrode layer 4031 do not have the same shape and do not overlap with each other in order to generate an electric field between the electrodes. Note that a structure may be employed in which the second electrode layer 4031 having a flat plate shape is formed on and in contact with the planarization insulating layer 4040, and the first electrode layer 4034 having an opening pattern and serving as a pixel electrode is formed over the second electrode layer 4031 with the insulating layer 4042 interposed therebetween.

The first electrode layer 4034 and the second electrode layer 4031 can be formed using a light-transmitting conductive material such as indium oxide containing tungsten oxide, indium zinc oxide containing tungsten oxide, indium oxide containing titanium oxide, indium tin oxide containing titanium oxide, indium tin oxide, indium zinc oxide, indium tin oxide to which silicon oxide is added, or graphene.

Alternatively, the first electrode layer 4034 and the second electrode layer 4031 can be formed using one or more materials selected from metals such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), copper (Cu), and silver (Ag); an alloy of any of these metals; and a nitride of any of these metals.

A conductive composition containing a conductive high molecule (also referred to as a conductive polymer) can be used for the first electrode layer 4034 and the second electrode layer 4031.

A columnar spacer denoted by reference numeral 4035 is obtained by selective etching of an insulating layer and is provided in order to control the thickness of the liquid crystal layer 4008 (a cell gap). Alternatively, a spherical spacer may be used.

In the case of a horizontal electric field mode an example of which is illustrated in FIG. 5B, a liquid crystal composition exhibiting a blue phase for which an alignment film is unnecessary may be used for the liquid crystal layer 4008. In this case, the liquid crystal layer 4008 is in contact with the first electrode layer 4034 and the second electrode layer 4031.

The size of storage capacitor formed in the liquid crystal display device is set considering the leakage current of the transistor provided in the pixel portion or the like so that charge can be held for a predetermined period. The size of the storage capacitor may be set considering the off-state current of a transistor or the like. By using a transistor including the oxide semiconductor layer disclosed in this specification, it is enough to provide a storage capacitor having a capacitance that is ⅓ or less, preferably ⅕ or less of liquid crystal capacitance of each pixel.

In the transistor including an oxide semiconductor layer, which is disclosed in this specification, the current in an off state (off-state current) can be made small. Accordingly, an electric signal such as image data can be held for a longer period and a writing interval can be set longer. Thus, the frequency of refresh operation can be reduced, which leads to an effect of suppressing power consumption.

The transistor which includes the oxide semiconductor layer disclosed in this specification can have high field-effect mobility and thus can operate at high speed. For example, when such a transistor is used for a liquid crystal display device, a switching transistor in a pixel portion and a driver transistor in a driver circuit portion can be formed over one substrate. In addition, by using such a transistor in a pixel portion, a high-quality image can be provided.

In the display device, a black matrix (a light-blocking layer), an optical member (an optical substrate) such as a polarizing member, a retardation member, or an anti-reflection member, and the like are provided as appropriate. For example, circular polarization may be obtained by using a polarizing substrate and a retardation substrate. In addition, a backlight, a side light, or the like may be used as a light source.

As a display method in the pixel portion, a progressive method, an interlace method or the like can be employed. Further, color elements controlled in a pixel at the time of color display are not limited to three colors: R, G, and B (R, G, and B correspond to red, green, and blue, respectively). For example, R, G, B, and W (W corresponds to white); R, G, B, and one or more of yellow, cyan, magenta, and the like; or the like can be used. Further, the sizes of display regions may be different between respective dots of color elements. Note that the disclosed invention is not limited to the application to a display device for color display; the disclosed invention can also be applied to a display device for monochrome display.

Alternatively, as the display element included in the display device, a light-emitting element utilizing electroluminescence can be used.

In order to extract light emitted from the light-emitting element, at least one of the pair of electrodes has a light-transmitting property. A transistor and a light-emitting element are formed over a substrate. The light-emitting element can have a top emission structure in which light emission is extracted through the surface opposite to the substrate; a bottom emission structure in which light emission is extracted through the surface on the substrate side; or a dual emission structure in which light emission is extracted through the surface opposite to the substrate and the surface on the substrate side, and a light-emitting element having any of these emission structures can be used.

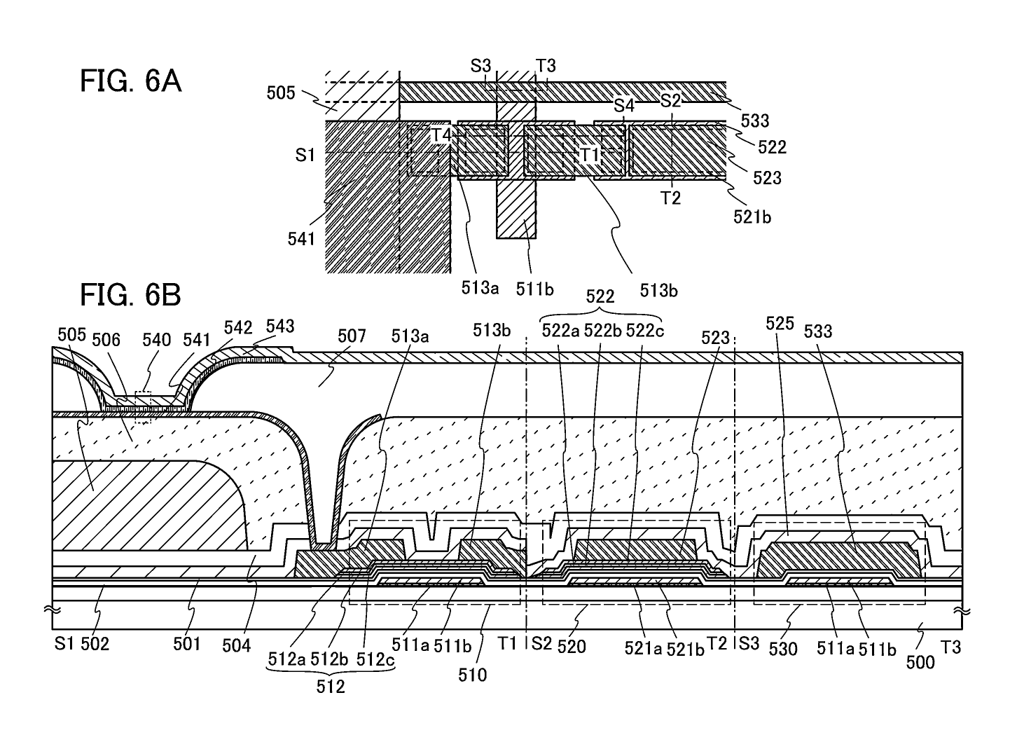

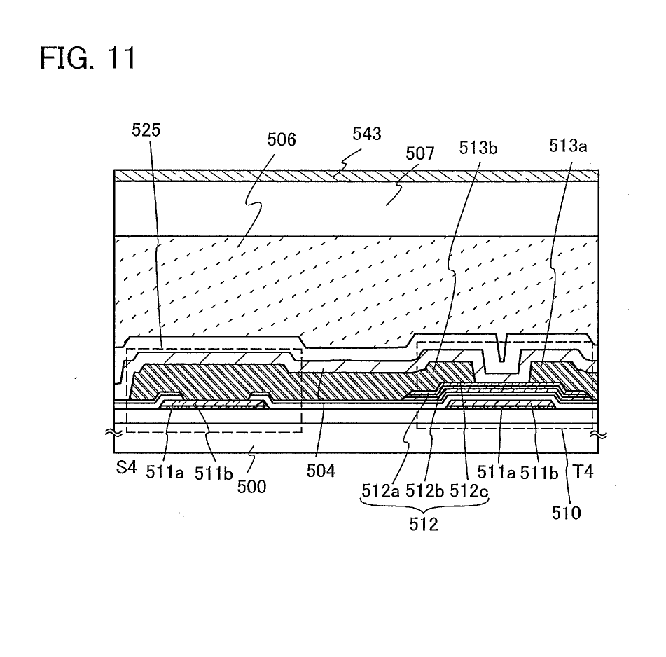

An example of a display device in which a light-emitting element is used as a display element is illustrated in FIGS. 6A and 6B and FIG. 11.

FIG. 6A is a plan view of the light-emitting device, and FIG. 6B is a cross-sectional view taken along dashed-dotted lines S1-T1, S2-T2, and S3-T3 in FIG. 6A. FIG. 11 is a cross-sectional view taken along dashed-dotted line S4-T4 in FIG. 6A. Note that an electroluminescent layer 542 and a second electrode layer 543 are not illustrated in the plan view in FIG. 6A.

The light-emitting device illustrated in FIGS. 6A and 6B includes, over a substrate 500, a transistor 510, a capacitor 520, and a wiring layer intersection 530. The transistor 510 is electrically connected to a light-emitting element 540. Note that FIGS. 6A and 6B illustrate a bottom-emission light-emitting device in which light from the light-emitting element 540 is extracted through the substrate 500.

The transistor described in Embodiment 1 can be applied to the transistor 510. In this embodiment, an example in which a transistor having a structure similar to that of the transistor 320 described in Embodiment 1 is used is described. The transistor 510 is a bottom-gate transistor.

The transistor 510 includes gate electrode layers 511a and 511b, gate insulating layers 501 and 502, an oxide semiconductor stack 512 which includes a first oxide semiconductor layer 512a including a stabilizer, a second oxide semiconductor layer 512b which includes a crystalline portion and is formed of an indium zinc oxide layer, and a third oxide semiconductor layer 512c including a stabilizer, and conductive layers 513a and 513b serving as source and drain electrode layers. In addition, an insulating layer 525 is formed over the transistor 510.

The capacitor 520 includes conductive layers 521a and 521b, the gate insulating layers 501 and 502, an oxide semiconductor stack 522 which includes a first oxide semiconductor layer 522a including a stabilizer, a second oxide semiconductor layer 522b which includes a crystalline portion and is formed of an indium zinc oxide layer, and a third oxide semiconductor layer 522c including a stabilizer, and a conductive layer 523. The gate insulating layers 501 and 502 and the oxide semiconductor stack 522 are sandwiched between the conductive layer 523 and the conductive layers 521a and 521b, whereby the capacitor is formed.

The wiring layer intersection 530 is an intersection of a conductive layer 533 and the gate electrode layers 511a and 511b. The conductive layer 533 and the gate electrode layers 511a and 511b intersect with each other with the gate insulating layers 501 and 502 interposed therebetween.

In this embodiment, a 30-nm-thick titanium film is used as each of the gate electrode layer 511a and the conductive layer 521a, and a 200-nm-thick copper thin film is used as each of the gate electrode layer 511b and the conductive layer 521b. Thus, the gate electrode layer has a stacked-layer structure of the titanium film and the copper thin film.

The transistor 510 includes an indium zinc oxide layer as the second oxide semiconductor layer which serves as a current path (channel) and includes a crystalline portion, and a first oxide semiconductor layer including a stabilizer and a third oxide semiconductor layer between which the second oxide semiconductor layer is sandwiched. Thus, the transistor 510 is a buried channel transistor in which a current path is positioned away from an interface with the insulating layer, and therefore has high field-effect mobility. In addition, the transistor 510 is a highly reliable transistor in which influence of an interface state which can be formed on the back channel side is reduced and photodegradation (e.g., negative-bias temperature stress photodegradation) is reduced.

An interlayer insulating layer 504 is formed over the transistor 510, the capacitor 520, and the wiring layer intersection 530. Over the interlayer insulating layer 504, a color filter layer 505 is provided in a region overlapping with the light-emitting element 540. An insulating layer 506 serving as a planarization insulating layer is provided over the interlayer insulating layer 504 and the color filter layer 505.

The light-emitting element 540 having a stacked-layer structure in which a first electrode layer 541, the electroluminescent layer 542, and the second electrode layer 543 are stacked in that order is provided over the insulating layer 506. The first electrode layer 541 and the conductive layer 513a are in contact with each other in an opening formed in the insulating layer 506 and the interlayer insulating layer 504, which reaches the conductive layer 513a; thus the light-emitting element 540 and the transistor 510 are electrically connected to each other. Note that a partition 507 is provided so as to cover part of the first electrode layer 541 and the opening.

As the color filter layer 505, for example, a chromatic light-transmitting resin can be used.

The partition 507 can be formed using an organic insulating material or an inorganic insulating material.

The electroluminescent layer 542 may be formed using either a single layer or a stack of a plurality of layers.

A protective film may be formed over the second electrode layer 543 and the partition 507 in order to prevent entry of oxygen, hydrogen, moisture, carbon dioxide, or the like into the light-emitting element 540. As the protective film, a silicon nitride film, a silicon nitride oxide film, a DLC film, or the like can be formed.

Further, the light-emitting element 540 may be covered with a layer containing an organic compound deposited by an evaporation method so that oxygen, hydrogen, moisture, carbon dioxide, or the like do not enter the light-emitting element 540.

In addition, as needed, an optical film such as a polarizing plate, a circularly polarizing plate (including an elliptically polarizing plate), a retardation plate (a quarter-wave plate or a half-wave plate), or a color filter may be provided as appropriate on a light-emitting surface of the light-emitting element. Further, the polarizing plate or the circularly polarizing plate may be provided with an anti-reflection film. For example, anti-glare treatment by which reflected light can be diffused by projections and depressions on the surface so as to reduce the glare can be performed.

Further, electronic paper in which electronic ink is driven (also referred to as electrophoretic display device or electrophoretic display) can be provided as a display device.

The insulating layer 506 serving as a planarization insulating layer can be formed using an organic material having heat resistance, such as an acrylic resin, polyimide, a benzocyclobutene-based resin, polyamide, or an epoxy resin. Other than such organic materials, it is also possible to use a low-dielectric constant material (low-k material) such as a siloxane-based resin, phosphosilicate glass (PSG), or borophosphosilicate glass (BPSG). Note that the insulating layer 506 may be formed by stacking a plurality of insulating layers formed using any of these materials.

Materials similar to those of the first electrode layer 4034 and the second electrode layer 4031 illustrated in FIGS. 5A and 5B can be used for the first electrode layer 541 and the second electrode layer 543.

In this embodiment, since the light-emitting device illustrated in FIGS. 6A and 6B has a bottom-emission structure, the first electrode layer 541 has a light-transmitting property and the second electrode layer 543 has a light-reflecting property. Accordingly, in the case of using a metal film as the first electrode layer 541, the film is preferably thin enough to keep the light-transmitting property; meanwhile, in the case of using a light-transmitting conductive film as the second electrode layer 543, a conductive layer having a light-reflecting property is preferably stacked thereon.

A protective circuit for protecting the driver circuit may be provided. The protection circuit is preferably formed using a nonlinear element.

As described above, any of the transistors described in Embodiment 1 is applied to a display device, so that the display device can have a variety of functions.

The methods, structures, and the like described in this embodiment can be combined as appropriate with any of the methods, structures, and the like described in the other embodiments.

### Embodiment 3

A semiconductor device having an image sensor function of reading information on an object can be manufactured using any of the transistors described in Embodiment 1.

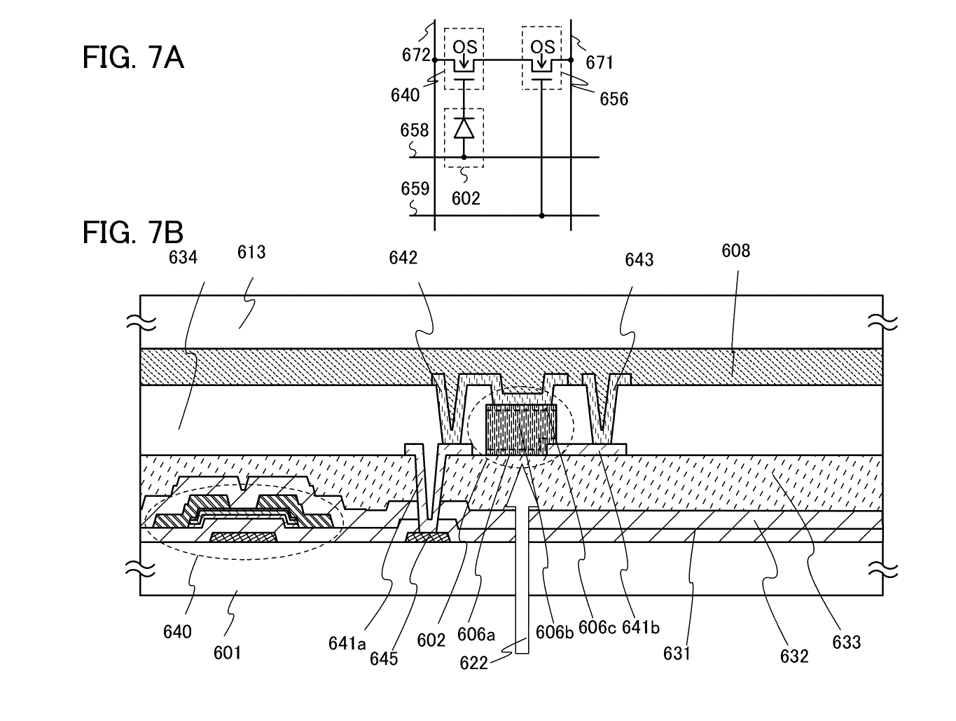

An example of a semiconductor device having an image sensor function is illustrated in FIG. 7A. FIG. 7A illustrates an equivalent circuit of a photo sensor, and FIG. 7B is a cross-sectional view of part of the photo sensor.

In a photodiode 602, one electrode is electrically connected to a photodiode reset signal line 658, and the other electrode is electrically connected to a gate of a transistor 640. One of a source and a drain of the transistor 640 is electrically connected to a photo sensor reference signal line 672, and the other of the source and the drain thereof is electrically connected to one of a source and a drain of a transistor 656. A gate of the transistor 656 is electrically connected to a gate signal line 659, and the other of the source and the drain thereof is electrically connected to a photo sensor output signal line 671.

Note that in circuit diagrams in this specification, a transistor using an oxide semiconductor layer is denoted by a symbol “OS” so that it can be identified as a transistor including an oxide semiconductor layer. In FIG. 7A, each of the transistor 640 and the transistor 656 is a transistor using an oxide semiconductor layer, to which the transistor described in Embodiment 1 can be applied. In this embodiment, an example in which a transistor having a structure similar to that of the transistor 320 described in Embodiment 1 is used is described. The transistor 640 is a bottom-gate transistor.

FIG. 7B is a cross-sectional view of the photodiode 602 and the transistor 640 in the photosensor. The transistor 640 and the photodiode 602 serving as a sensor are provided over a substrate 601 (an element substrate) having an insulating surface. A substrate 613 is provided over the photodiode 602 and the transistor 640 with an adhesive layer 608 interposed therebetween.

An insulating layer 632, an interlayer insulating layer 633, and an interlayer insulating layer 634 are provided over the transistor 640. The photodiode 602 includes an electrode layer 641b formed over the interlayer insulating layer 633, semiconductor films (a first semiconductor film 606a, a second semiconductor film 606b, and a third semiconductor film 606c stacked over the electrode layer 641b in this order), an electrode layer 642 which is provided over the interlayer insulating layer 634 and electrically connected to the electrode layer 641b through the first to third semiconductor films, and an electrode layer 641a which is provided in the same layer as the electrode layer 641b and electrically connected to the electrode layer 642.

The electrode layer 641b is electrically connected to a conductive layer 643 formed over the interlayer insulating layer 634, and the electrode layer 642 is electrically connected to a conductive layer 645 through the electrode layer 641a. The conductive layer 645 is electrically connected to a gate electrode layer of the transistor 640, and the photodiode 602 is electrically connected to the transistor 640.

Here, a pin photodiode in which a semiconductor film having p-type conductivity as the first semiconductor film 606a, a high-resistance semiconductor film (i-type semiconductor film) as the second semiconductor film 606b, and a semiconductor film having n-type conductivity as the third semiconductor film 606c are stacked is illustrated as an example.

The first semiconductor film 606a is a p-type semiconductor film and can be formed using an amorphous silicon film containing an impurity element imparting p-type conductivity type. The first semiconductor film 606a is formed by a plasma CVD method with the use of a semiconductor source gas containing an impurity element belonging to Group 13 (e.g., boron (B)). As the semiconductor material gas, silane (SiH₄) may be used. Alternatively, Si₂H₆, SiH₂Cl₂, SiHCl₃, SiCl₄, SiF₄, or the like may be used. Further alternatively, an amorphous silicon film which does not contain an impurity element may be formed, and then, an impurity element may be introduced to the amorphous silicon film with use of a diffusion method or an ion injecting method. Heating or the like may be conducted after introducing the impurity element by an ion injecting method or the like in order to diffuse the impurity element. In this case, as a method of forming the amorphous silicon film, an LPCVD method, a chemical vapor deposition method, a sputtering method, or the like may be used. The first semiconductor film 606a is preferably formed to a thickness greater than or equal to 10 nm and less than or equal to 50 nm.

The second semiconductor film 606b is an i-type semiconductor film (intrinsic semiconductor film) and is formed using an amorphous silicon film. As for formation of the second semiconductor film 606b, an amorphous silicon film is formed by a plasma CVD method with the use of a semiconductor source gas. As the semiconductor material gas, silane (SiH₄) may be used. Alternatively, Si₂H₆, SiH₂Cl₂, SiHCl₃, SiCl₄, SiF₄, or the like may be used. The second semiconductor film 606b may be formed by an LPCVD method, a vapor deposition method, a sputtering method, or the like. The second semiconductor film 606b is preferably formed to a thickness greater than or equal to 200 nm and less than or equal to 1000 nm.

The third semiconductor film 606c is an n-type semiconductor film and is formed using an amorphous silicon film containing an impurity element imparting n-type conductivity type. The third semiconductor film 606c is formed by a plasma CVD method with the use of a semiconductor source gas containing an impurity element belonging to Group 15 (e.g., phosphorus (P)). As the semiconductor material gas, silane (SiH₄) may be used. Alternatively, Si₂H₆, SiH₂Cl₂, SiHCl₃, SiCl₄, SiF₄, or the like may be used. Further alternatively, an amorphous silicon film which does not contain an impurity element may be formed, and then, an impurity element may be introduced to the amorphous silicon film with use of a diffusion method or an ion injecting method. Heating or the like may be conducted after introducing the impurity element by an ion injecting method or the like in order to diffuse the impurity element. In this case, as a method of forming the amorphous silicon film, an LPCVD method, a chemical vapor deposition method, a sputtering method, or the like may be used. The third semiconductor film 606c is preferably formed to a thickness greater than or equal to 20 nm and less than or equal to 200 nm.

The first semiconductor film 606a, the second semiconductor film 606b, and the third semiconductor film 606c are not necessarily formed using an amorphous semiconductor, and may be formed using a polycrystalline semiconductor or a microcrystalline semiconductor (semi-amorphous semiconductor: SAS).

Since the mobility of holes generated by the photoelectric effect is lower than that of electrons, a PIN photodiode has better characteristics when a surface on the p-type semiconductor film side is used as a light-receiving surface. Here, an example in which light received by the photodiode 602 from a surface of the substrate 601, over which the PIN photodiode is formed, is converted into electric signals is described. Further, light from the semiconductor film having the conductivity type opposite to that of the semiconductor film on the light-receiving plane is disturbance light; therefore, the electrode layer is preferably formed using a light-blocking conductive layer. Note that the n-type semiconductor film side may alternatively be a light-receiving surface.

The transistor 640 includes an indium zinc oxide layer as the second oxide semiconductor layer which serves as a current path (channel) and includes a crystalline portion, and a first oxide semiconductor layer including a stabilizer and a third oxide semiconductor layer between which the second oxide semiconductor layer is sandwiched. Thus, the transistor 640 is a buried channel transistor in which a current path is positioned away from an interface with the insulating layer, and therefore has high field-effect mobility. In addition, the transistor 640 is a highly reliable transistor in which influence of an interface state which can be formed on the back channel side is reduced and photodegradation (e.g., negative-bias temperature stress photodegradation) is reduced.

For a reduction in surface roughness, an insulating layer serving as a planarization insulating layer is preferably used as each of the interlayer insulating layers 633 and 634.

With detection of light 622 that enters the photodiode 602, data on an object can be read. Note that a light source such as a backlight can be used at the time of reading data on an object.

The methods, structures, and the like described in this embodiment can be combined as appropriate with any of the methods, structures, and the like described in the other embodiments.

### Embodiment 4

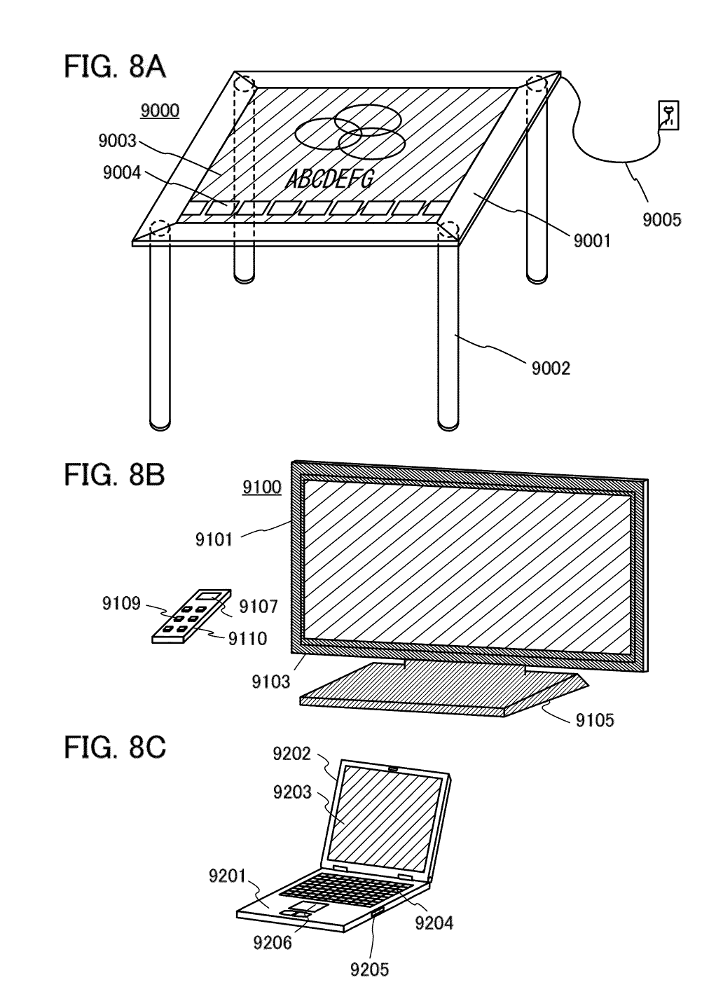

A semiconductor device disclosed in this specification can be applied to a variety of electronic appliances (including game machines). Examples of electronic appliances include a television set (also referred to as a television or a television receiver), a monitor of a computer or the like, cameras such as a digital camera and a digital video camera, a digital photo frame, a mobile phone, a portable game machine, a portable information terminal, an audio reproducing device, a game machine (e.g., a pachinko machine or a slot machine), a game console, and the like. Specific examples of these electronic appliances are illustrated in FIGS. 8A to 8C.

FIG. 8A illustrates a table 9000 having a display portion. In the table 9000, a display portion 9003 is incorporated in a housing 9001 and an image can be displayed on the display portion 9003. Note that the housing 9001 is supported by four leg portions 9002. Further, the housing 9001 is provided with a power cord 9005 for supplying power.

The semiconductor device described in any of the above embodiments can be used for the display portion 9003, so that the electronic appliance can have high reliability.

The display portion 9003 has a touch-input function. When a user touches displayed buttons 9004 which are displayed on the display portion 9003 of the table 9000 with his/her finger or the like, the user can carry out operation of the screen and input of information. Further, when the table may be made to communicate with home appliances or control the home appliances, the table 9000 may function as a control device which controls the home appliances by operation on the screen. For example, with use of the semiconductor device having an image sensor described in Embodiment 3, the display portion 9003 can function as a touch panel.

Further, the screen of the display portion 9003 can be placed perpendicular to a floor with a hinge provided for the housing 9001; thus, the table 9000 can also be used as a television device. When a television device having a large screen is set in a small room, an open space is reduced; however, when a display portion is incorporated in a table, a space in the room can be efficiently used.

FIG. 8B illustrates a television device 9100. In the television device 9100, a display portion 9103 is incorporated in a housing 9101 and an image can be displayed on the display portion 9103. Note that the housing 9101 is supported by a stand 9105 here.

The television device 9100 can be operated with an operation switch of the housing 9101 or a separate remote controller 9110. Channels and volume can be controlled with an operation key 9109 of the remote controller 9110 so that an image displayed on the display portion 9103 can be controlled. Furthermore, the remote controller 9110 may be provided with a display portion 9107 for displaying data output from the remote controller 9110.

The television device 9100 illustrated in FIG. 8B is provided with a receiver, a modem, and the like. With the use of the receiver, the television device 9100 can receive general TV broadcasts. Moreover, when the television device 9100 is connected to a communication network with or without wires via the modem, one-way (from a sender to a receiver) or two-way (between a sender and a receiver or between receivers) information communication can be performed.

The semiconductor device described in any of the above embodiments can be used in the display portions 9103 and 9107, so that the television device and the remote controller can have high reliability.

FIG. 8C illustrates a computer, which includes a main body 9201, a housing 9202, a display portion 9203, a keyboard 9204, an external connection port 9205, a pointing device 9206, and the like.

The semiconductor device described in any of the above embodiments can be used for the display portion 9203, so that the computer can have high reliability.

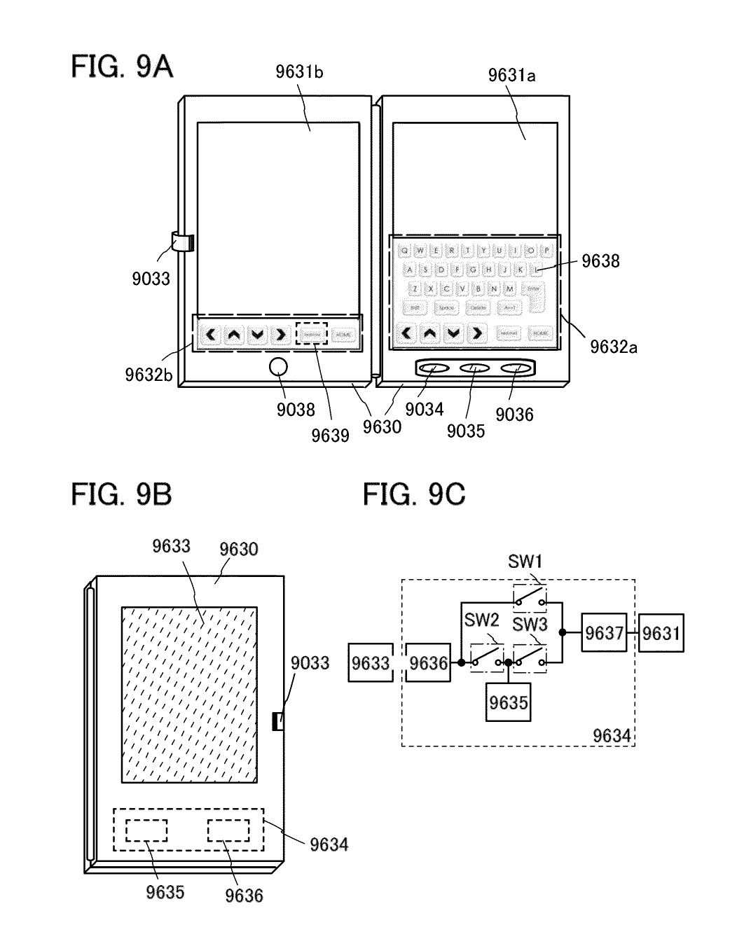

FIGS. 9A and 9B illustrate a tablet terminal that can be folded. In FIG. 9A, the tablet terminal is opened, and includes a housing 9630, a display portion 9631a, a display portion 9631b, a display-mode switching button 9034, a power button 9035, a power-saving-mode switching button 9036, a clip 9033, and an operation button 9038.

The semiconductor device described in any of the above embodiments can be used for the display portion 9631a and the display portion 9631b, so that the tablet terminal can have high reliability.

Part of the display portion 9631a can be a touch panel region 9632a, and data can be input by touching operation keys 9638 displayed. Although a structure in which a half region in the display portion 9631a has only a display function and the other half region also has a touch panel function is illustrated as an example, the structure of the display portion 9631a is not limited thereto. The whole display portion 9631a may have a touch panel function. For example, a keyboard is displayed on the whole display portion 9631a so that the display portion 9631a serves as a touch panel; thus, the display portion 9631b can be used as a display screen.

As in the display portion 9631a, part of the display portion 9631b can be a touch panel region 9632b. When a keyboard display switching button 9639 displayed on the touch panel is touched with a finger, a stylus, or the like, a keyboard can be displayed on the display portion 9631b.

Touch input can be performed in the touch panel region 9632a and the touch panel region 9632b at the same time.

The display-mode switching button 9034 can switch the display between portrait mode, landscape mode, and the like, and between monochrome display and color display, for example. With the button 9036 for switching to power-saving mode, the luminance of display can be optimized in accordance with the amount of external light at the time when the tablet is in use, which is detected with an optical sensor incorporated in the tablet. The tablet may include another detection device such as a sensor for detecting orientation (e.g., a gyroscope or an acceleration sensor) in addition to the optical sensor.

Although the display portion 9631a and the display portion 9631b have the same display area in FIG. 9A, an embodiment of the present invention is not limited to this example. The display portion 9631a and the display portion 9631b may have different areas or different display quality. For example, one of them may be a display panel that can display higher-definition images than the other.

In FIG. 9B, the tablet terminal is folded, and includes the housing 9630, a solar battery 9633, and a charge and discharge control circuit 9634. FIG. 9B illustrates a structure including a battery 9635 and a DCDC converter 9636 as an example of the charge and discharge control circuit 9634.

Since the tablet terminal can be folded in two, the housing 9630 can be closed when the tablet terminal is not in use. Thus, the display portions 9631a and 9631b can be protected, thereby providing a tablet with high endurance and high reliability for long-term use.

The tablet terminal illustrated in FIGS. 9A and 9B can have other functions such as a function of displaying various kinds of data (e.g., a still image, a moving image, and a text image), a function of displaying a calendar, a date, the time, or the like on the display portion, a touch-input function of operating or editing the data displayed on the display portion by touch input, and a function of controlling processing by various kinds of software (programs).

The solar battery 9633, which is attached on the surface of the tablet terminal, supplies electric power to a touch panel, a display portion, an image signal processor, and the like. Note that the solar battery 9633 can be provided on one or two surfaces of the housing 9630, so that the battery 9635 can be charged efficiently. When a lithium ion battery is used as the battery 9635, there is an advantage of downsizing or the like.

The structure and operation of the charge and discharge control circuit 9634 illustrated in FIG. 9B are described with reference to a block diagram of FIG. 9C. FIG. 9C illustrates the solar battery 9633, the battery 9635, the DCDC converter 9636, a converter 9637, switches SW1 to SW3, and the display portion 9631. The battery 9635, the DCDC converter 9636, the converter 9637, and the switches SW1 to SW3 correspond to the charge and discharge control circuit 9634 in FIG. 9B.

First, an example of operation in the case where power is generated by the solar battery 9633 using external light is described. The voltage of power generated by the solar battery 9633 is raised or lowered by the DCDC converter 9636 so that a voltage for charging the battery 9635 is obtained. When the display portion 9631 is operated with the power from the solar battery 9633, the switch SW1 is turned on and the voltage of the power is raised or lowered by the converter 9637 to a voltage needed for operating the display portion 9631. In addition, when display on the display portion 9631 is not performed, the switch SW1 is turned off and a switch SW2 is turned on so that charge of the battery 9635 may be performed.

Here, the solar battery 9633 is shown as an example of a power generation means; however, there is no particular limitation on a way of charging the battery 9635, and the battery 9635 may be charged with another power generation means such as a piezoelectric element or a thermoelectric conversion element (Peltier element). For example, the battery 9635 may be charged with a non-contact power transmission module that transmits and receives power wirelessly (without contact) to charge the battery or with a combination of other charging means.

The methods, structures, and the like described in this embodiment can be combined as appropriate with any of the methods, structures, and the like described in the other embodiments.

### Example

In this example, evaluation results of crystalline states of indium zinc oxide films which can be used for channels of the transistors described in the above embodiments is described.

Five samples were manufactured as samples of this example. Methods for manufacturing the samples are described below.

### Example Sample A1

An indium zinc oxide film was formed to a thickness of 100 nm over a quartz substrate by a sputtering method.

The indium zinc oxide film was formed using a sputtering target with a composition ratio of In:Zn=2:1 (In₂O₃:Zn=1:1 in a molar ratio) at a substrate temperature of 200° C. in an oxygen (flow rate: 15 sccm) atmosphere.

### Example Sample A2

An indium zinc oxide film was formed to a thickness of 100 nm over a quartz substrate by a sputtering method.

The indium zinc oxide film was formed using a sputtering target with a composition ratio of In:Zn=2:1 (In₂O₃:Zn=1:1 in a molar ratio) at a substrate temperature of 200° C. in an argon and oxygen atmosphere (argon flow rate: 10.5 sccm and oxygen flow rate: 4.5 sccm).

### Example Sample B1

A silicon oxide film was formed to a thickness of 300 nm over a quartz substrate by a sputtering method, and then an indium zinc oxide film was formed to a thickness of 100 nm over the silicon oxide film by a sputtering method.

The silicon oxide film was formed using a silicon oxide (SiO₂) target as a target under the conditions where the pressure was 0.4 Pa, the power of an RF power source was 2 kW, the atmosphere was an argon and oxygen atmosphere (argon flow rate: 25 sccm and oxygen flow rate: 25 sccm), and the substrate temperature was 100° C.

The indium zinc oxide film was formed using a sputtering target with a composition ratio of In:Zn=2:1 (In₂O₃:Zn=1:1 in a molar ratio) at a substrate temperature of 200° C. in an oxygen (flow rate: 15 sccm) atmosphere.

### Example Sample C1

A silicon oxynitride film was formed to a thickness of 300 nm over a quartz substrate by a CVD method, and then an indium zinc oxide film was formed to a thickness of 100 nm over the silicon oxide film by a sputtering method.

The indium zinc oxide film was formed using a sputtering target with a composition ratio of In:Zn=2:1 (In₂O₃:Zn=1:1 in a molar ratio) at a substrate temperature of 200° C. in an oxygen (flow rate: 15 sccm) atmosphere.

### Example Sample C2

A silicon oxynitride film was formed to a thickness of 300 nm over a quartz substrate by a CVD method, and then an indium zinc oxide film was formed to a thickness of 100 nm over the silicon oxynitride film by a sputtering method.

The indium zinc oxide film was formed using a sputtering target with a composition ratio of In:Zn=2:1 (In₂O₃:Zn=1:1 in a molar ratio) at a substrate temperature of 200° C. in an argon and oxygen atmosphere (argon flow rate: 10.5 sccm and oxygen flow rate: 4.5 sccm).

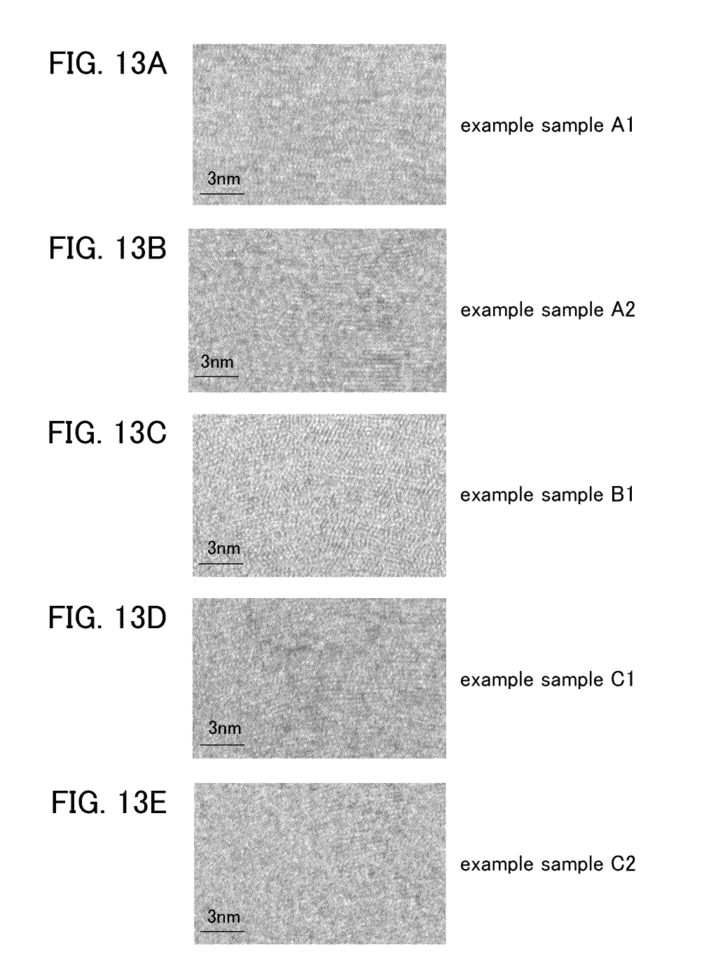

Each of the example samples A1, A2, B1, C1, and C2 obtained through the above steps was cut to expose a cross-section of an end plane of the indium zinc oxide film, and the cross-section was observed with a high-resolution transmission electron microscope (TEM) (H9000-NAR manufactured by Hitachi High-Technologies Corporation) at an acceleration voltage of 300 kV. FIGS. 13A to 13E show TEM images (magnification: 8 million times) of the example samples A1, A2, B1, C1, and C2, respectively.

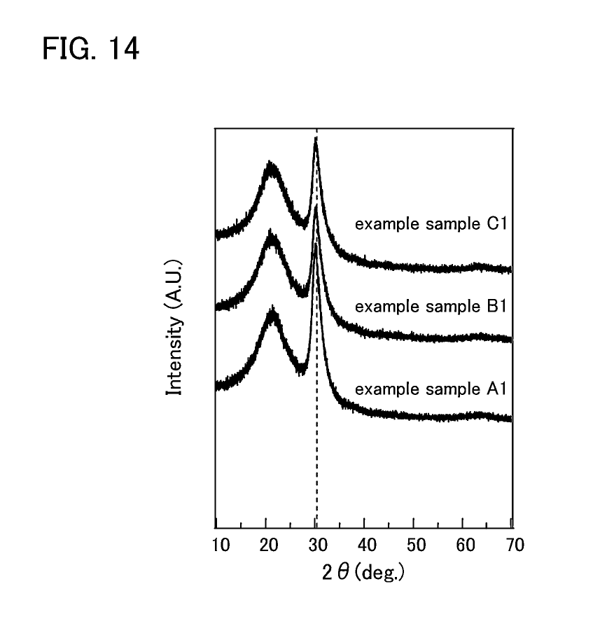

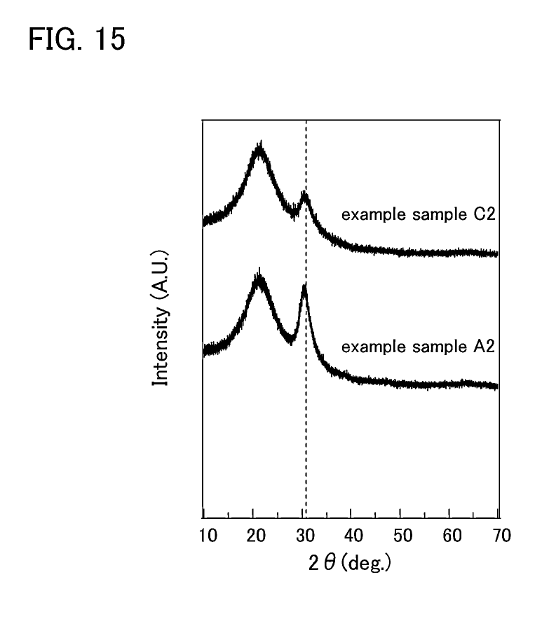

The indium zinc oxide film of each of the example samples A1, A2, B1, C1, and C2 were subjected to X-ray diffraction (XRD) measurement. FIG. 14 shows XRD spectra of the example samples A1, B1, and C1 measured by an out-of-plane method. FIG. 15 shows XRD spectra of the example samples A2 and C2 measured by an out-of-plane method.

In each of FIG. 14 and FIG. 15, the vertical axis represents the X-ray diffraction intensity (given unit) and the horizontal axis represents the rotation angle 2θ (degree). Note that the XRD spectra were measured with an X-ray diffractometer, D8 ADVANCE manufactured by Bruker AXS.

FIGS. 13A to 13E demonstrate that every example sample manufactured in this example had a crystalline portion in which crystals were arranged in a layered manner. According to the XRD spectra shown in FIG. 14 and FIG. 15, peaks attributed to diffraction on the (009) plane of the indium zinc oxide crystal were observed in a region where 2 θ is in the vicinity of 31° in the example samples. The results demonstrate that the example samples manufactured in this example are each a CAAC-OS film which has a c-axis substantially perpendicular to a surface of the film.

In a transistor in which such an oxide semiconductor film including a crystalline portion having a c-axis substantially perpendicular to a surface (CAAC-OS film) is provided, variations in electrical characteristics of the transistor due to irradiation with visible light or ultraviolet light can be suppressed. Therefore, a highly reliable semiconductor device can be provided.

This application is based on Japanese Patent Application serial no. 2012-157653 filed with Japan Patent Office on Jul. 13, 2012, the entire contents of which are hereby incorporated by reference.

What is claimed is:

1. A semiconductor device comprising:
a gate electrode layer;
a gate insulating layer over the gate electrode layer;
an oxide semiconductor stack overlapping with the gate electrode layer with the gate insulating layer interposed therebetween; and
a source electrode layer and a drain electrode layer electrically connected to the oxide semiconductor stack,
wherein the oxide semiconductor stack comprises a first oxide semiconductor layer in contact with the gate insulating layer and a second oxide semiconductor layer over the first oxide semiconductor layer,
wherein the first oxide semiconductor layer contains indium and zinc, and has a larger energy gap than the second oxide semiconductor layer, and
wherein the second oxide semiconductor layer is an indium zinc oxide layer including a crystalline portion.

2. The semiconductor device according to claim 1, wherein the second oxide semiconductor layer contains a larger amount of indium than the first oxide semiconductor layer.

3. The semiconductor device according to claim 1, wherein the first oxide semiconductor layer contains one or more metal elements selected from the group consisting of gallium, magnesium, tin, hafnium, aluminum, zirconium, lanthanum, cerium, praseodymium, neodymium, samarium, europium, gadolinium, terbium, dysprosium, holmium, erbium, thulium, ytterbium, and lutetium.

4. The semiconductor device according to claim 1, wherein the first oxide semiconductor layer contains a constituent element of the gate insulating layer as an impurity.

5. The semiconductor device according to claim 1,
wherein a c-axis of the crystalline portion is aligned with a direction parallel to a normal vector of a surface where the indium zinc oxide layer is formed or a normal vector of a surface of the indium zinc oxide layer,
wherein in the crystalline portion, triangular or hexagonal atomic arrangement which is seen from a direction perpendicular to an a-b plane is formed, and
wherein in the crystalline portion, metal atoms are arranged in a layered manner or metal atoms and oxygen atoms are arranged in a layered manner when seen from a direction perpendicular to the c-axis.

6. The semiconductor device according to claim 1, wherein the semiconductor device is a display device.

7. A semiconductor device comprising:
a gate electrode layer;
a gate insulating layer over the gate electrode layer;
an oxide semiconductor stack overlapping with the gate electrode layer with the gate insulating layer interposed therebetween; and
a source electrode layer and a drain electrode layer electrically connected to the oxide semiconductor stack,
wherein the oxide semiconductor stack comprises a first oxide semiconductor layer in contact with the gate insulating layer, a second oxide semiconductor layer over the first oxide semiconductor layer, and a third oxide semiconductor layer over the second oxide semiconductor layer,
wherein the first oxide semiconductor layer and the third oxide semiconductor layer each contain indium and zinc, and have a larger energy gap than the second oxide semiconductor layer, and
wherein the second oxide semiconductor layer is an indium zinc oxide layer including a crystalline portion.

8. The semiconductor device according to claim 7, wherein the second oxide semiconductor layer contains a larger amount of indium than the first oxide semiconductor layer and the third oxide semiconductor layer.

9. The semiconductor device according to claim 7, wherein the first oxide semiconductor layer contains one or more metal elements selected from the group consisting of gallium, magnesium, tin, hafnium, aluminum, zirconium, lanthanum, cerium, praseodymium, neodymium, samarium, europium, gadolinium, terbium, dysprosium, holmium, erbium, thulium, ytterbium, and lutetium.

10. The semiconductor device according to claim 7, wherein the first oxide semiconductor layer contains a constituent element of the gate insulating layer as an impurity.

11. The semiconductor device according to claim 7,
wherein a c-axis of the crystalline portion is aligned with a direction parallel to a normal vector of a surface where the indium zinc oxide layer is formed or a normal vector of a surface of the indium zinc oxide layer,
wherein in the crystalline portion, triangular or hexagonal atomic arrangement which is seen from a direction perpendicular to an a-b plane is formed, and
wherein in the crystalline portion, metal atoms are arranged in a layered manner or metal atoms and oxygen atoms are arranged in a layered manner when seen from a direction perpendicular to the c-axis.

12. The semiconductor device according to claim 7, wherein the semiconductor device is a display device.
